(19) United States
(12) Patent Application Publication
(10) Pub. No.: US 2011/0170346 A1
(43) Pub. Date: Jul. 14, 2011

(54) NON-VOLATILE SEMICONDUCTOR MEMORY DEVICE, SIGNAL PROCESSING SYSTEM, METHOD FOR CONTROLLING SIGNAL PROCESSING SYSTEM, AND METHOD FOR REPROGRAMMING NON-VOLATILE SEMICONDUCTOR MEMORY DEVICE

(75) Inventors: Hiroyasu NAGAI, Osaka (JP); Masahiro Toki, Shiga (JP); Toshiki Mori, Osaka (JP)

(73) Assignee: PANASONIC CORPORATION, Osaka (JP)

(21) Appl. No.: 13/070,276

(22) Filed: Mar. 23, 2011

Related U.S. Application Data
(63) Continuation of application No. PCT/JP2010/004688, filed on Jul. 22, 2010.

(30) Foreign Application Priority Data
Oct. 5, 2009 (JP) 2009-231396

(51) Int. Cl. G11C 16/26

(52) U.S. Cl. 365/185.2

(57) ABSTRACT

A non-volatile semiconductor memory device includes a memory cell array including a data storage area and a reprogram information storage area, and a reprogram information holder circuit configured to store data read from the reprogram information storage area. A reference level switch circuit selects one from a plurality of read reference levels generated by a reference level generator circuit, based on an output of the reprogram information holder circuit. A read circuit reads memory cell data from the data storage area 104 based on the selected read reference level, and outputs the memory cell data. Therefore, a degradation in data hold capability due to reprogram operation is reduced or prevented. In addition, intended operation is achieved without being affected by interruption or resumption of power supply, a circuit size is reduced, and high-speed read operation is achieved.

### CROSS-REFERENCE TO RELATED APPLICATIONS

This is a continuation of PCT International Application PCT/JP2010/004688 filed on Jul. 22, 2010, which claims priority to Japanese Patent Application No. 2009-231396 filed on Oct. 5, 2009. The disclosures of these applications including the specifications, the drawings, and the claims are hereby incorporated by reference in their entirety.

### BACKGROUND

The present disclosure relates to non-volatile semiconductor memory devices which can be electrically programmed and erased, and signal processing systems including the non-volatile semiconductor memory device and a processor which controls the non-volatile semiconductor memory device.

There are two types of semiconductor memory devices: volatile memory which requires power to maintain its contents; and non-volatile memory which can maintain its contents without power supply. Examples of volatile memory include static random access memory (SRAM) and dynamic random access memory (DRAM). On the other hand, there are two types of non-volatile memory: non-volatile ROM; and non-volatile RAM. Examples of non-volatile ROM include flash memory (flash electrically erasable and programmable read only memory). Examples of non-volatile RAM include magneto-resistive random access memory (MRAM) and resistive random access memory (ReRAM). Although flash memory will be described hereinafter as an example of non-volatile memory, the present disclosure is not limited to flash memory.

In flash memory, each memory cell stores information by utilizing changes in the threshold voltage (hereinafter referred to as a memory cell threshold voltage Vt). A state where the memory cell threshold voltage Vt is low is defined as a logic 1 (erased state), and a state where the memory cell threshold voltage Vt is high is defined as a logic 0 (programmed state). An intermediate voltage between the high and low memory cell threshold voltages Vt is defined as a read reference level. The logic value (1 or 0) of each memory cell is determined based on whether or not a current flows through the memory cell.

FIG. 10 is a diagram showing distributions of memory cell threshold voltages Vt in a conventional flash memory device, where the horizontal axis indicates memory cell threshold voltages Vt and the vertical axis indicates numbers of memory cells. Reprogram operation of the flash memory device will be described hereinafter with reference to FIGS. 10A-10D.

In FIG. 10, a reference character 1001 indicates a distribution of memory cell threshold voltages Vt for the logic 1, a reference character 1002 indicates a distribution of memory cell threshold voltages Vt for the logic 0, a reference character 1003 indicates a read reference level, a reference character 1004 indicates a program verify level, a reference character 1005 indicates an erase verify level, a reference character 1006 indicates a distribution of memory cell threshold voltages Vt for logic 0, and a reference character 1007 indicates a distribution of memory cell threshold voltages Vt for the logic 1.

A portion (a) of FIG. 10 is a diagram showing distributions of memory cell threshold voltages Vt which are obtained after program operation. By program operation, a memory cell to be programmed is transitioned from the erased state to the program verify level 1004. The read reference level 1003 is set somewhere between the distribution 1001 of memory cell threshold voltages Vt for the logic 1 and the distribution 1002 of memory cell threshold voltages Vt for the logic 0. The read reference level 1003 is used to check whether or not a current flows through the memory cell. If so, the memory cell is determined to have the logic 1, and if not, the memory cell is determined to have the logic 0.

A portion (b) of FIG. 10 is a diagram showing a distribution of memory cell threshold voltages Vt which is obtained after preprogram operation. When data is rewritten, erase operation is performed before program operation. In flash memory, operation called “preprogram” is performed before erase operation. In flash memory, erase operation is performed in blocks, i.e., all the memory cells in a block are erased at a time, and therefore, the same erase stress is applied to the memory cells of the logic 1 and the memory cells of the logic 0. In this case, excessive erase stress is applied to the memory cells of the logic 1, which have the low memory cell threshold voltage Vt (specifically, because the application of erase stress is continued until the memory cells of the logic 0, which have the high memory cell threshold voltage Vt, transition to the erased state), leading to an adverse influence (e.g., a leakage current, etc.) on reliability. To reduce or prevent this, preprogram operation is performed before erase operation to cause all the memory cells to have a memory cell threshold voltage Vt which is present within the distribution 1006 for the logic 0.

A portion (c) of FIG. 10 is a diagram showing a distribution of memory cell threshold voltages Vt which is obtained after erase operation. The memory cells programmed to the logic 0 state by preprogram operation are transitioned to the erase verify level 1005 by erase operation.

As a result, the memory cells have the distribution 1007 of memory cell threshold voltages Vt for the logic 1. Thereafter, when program operation is performed, the flash memory device returns to the state of FIG. 10A.

A first problem with the above non-volatile memory is that the degradation of the program, erase, and data hold capabilities of memory cells is accelerated every time stored data is rewritten. Specifically, every time stored data is rewritten, erase operation is invariably performed to reset memory cells to the initial state, and therefore, electric field stress is applied to the insulating film etc. Damages are accumulated, leading to a degradation in the data hold capability.

A second problem is that it takes a long time to rewrite stored data. Specifically, preprogram operation and erase operation are performed in conjunction with each other before program operation every time stored data is rewritten, and therefore, the entire rewrite (reprogram) operation requires a long time.

To solve these problems, for example, Japanese Patent Publication No. H10-112193 has proposed that electric field stress applied to the insulating film etc. is reduced by decreasing the number of erase operations for resetting memory cells to the initial state every time stored data is rewritten, thereby reducing or preventing the degradation of the data hold capability. In this technique, a memory cell which has three or more possible threshold voltages, and a plurality of read reference levels, are used, and the read reference levels are changed in reprogram operation, thereby reducing the number of erase operations.

A flash memory device described in Japanese Patent Publication No. H10-112193 will be described hereinafter.

FIG. 11 is a diagram showing regions where memory cell threshold voltages Vt are set in the flash memory device. Note that memory cell threshold voltages Vt can be set between the minimum memory cell threshold voltage Vt (Vtmin) and the maximum memory cell threshold voltage Vt (Vtmax), and are set to a low level by erase operation.

In FIG. 11, reference characters B1, B2, and B3-Bi indicate the regions in which memory cell threshold voltages Vt are set and which are set between the minimum value Vtmin and the maximum values Vtmax of memory cell threshold voltages Vt. Reference characters VR1, VR2, and VR3-VRi-1 indicate read reference levels.

FIG. 12 is a diagram showing data states in the case where the flash memory device stores binary information. Initially, in the first program operation, data stored in all the memory cells is erased, the memory cell threshold voltage Vt is set to the setting region B1 (logic 1), and data write is performed to increase the memory cell threshold voltage Vt for storing the logic 0 to the setting region B2. In this state, when stored data is read out, the read reference level is set to VR1. It is determined whether the memory cell threshold voltage Vt is lower or higher than this read reference level. When the memory cell threshold voltage Vt is lower than the read reference level, the memory cell is determined to have the logic 1, and when the memory cell threshold voltage Vt is higher than the read reference level, the memory cell is determined to have the logic 0.

In the second program operation, erase operation is not performed, and the memory cell threshold voltage Vt for storing the logic 0 is increased to the setting region B3. In this state, when stored data is read out, the read reference level is set to VR2. It is determined whether the memory cell threshold voltage Vt is lower or higher than this read reference level. When the memory cell threshold voltage Vt is lower than the read reference level, the memory cell is determined to have the logic 1, and when the memory cell threshold voltage Vt is higher than the read reference level, the memory cell is determined to have the logic 0. Therefore, stored data of a memory cell whose memory cell threshold voltage Vt is present within the setting region B1 or B2 is the logic 1.

This means that the data of a memory cell whose memory cell threshold voltage Vt is present within the setting region B2 has been changed from the logic 0 to the logic 1.

Similarly, in the m-th program operation, the memory cell threshold voltage Vt for storing the logic 0 is increased to the setting region Bi. In this state, when stored data is read out, the read reference level is set to VRi-1. It is determined whether the memory cell threshold voltage Vt is lower or higher than this read reference level. When the memory cell threshold voltage Vt is lower than the read reference level, the memory cell is determined to have the logic 1, and when the memory cell threshold voltage Vt is higher than the read reference level, the memory cell is determined to have the logic 0. Therefore, stored data of a memory cell whose memory cell threshold voltage Vt is present within any of the setting regions B1 and B2-Bi-1 is the logic 1.

In the (m+1)th program operation, because all the setting regions for the memory cell threshold voltage Vt have been used, as in the first program operation erase operation is performed before data write to erase stored data of all the memory cells, and the memory cell threshold voltage Vt is set back to the setting region B1 (logic 1), and thereafter, data write is performed to increase the memory cell threshold voltage Vt for storing the logic 0 to the setting region B2. At the same time, the read reference level is set back to VR1.

Thus, erase operation is performed only once every m program operations. Therefore, the time required for (m−1) erase operations is removed, whereby data rewrite is sped up, and electric field stress applied to the insulating film etc. is reduced by a factor of m, whereby the program, erase, and data hold capabilities of memory cells can be reduced or prevented.

FIG. 13 is a block diagram showing a circuit configuration of a flash memory device for achieving the reprogram operation of FIGS. 11 and 12. The flash memory device includes: a memory cell array 1301 having a plurality of sectors 0-i, sector status registers 0-i 1302 which count the number of data write (program) operations; a reference level generator circuit 1303 which generates read and program reference levels; a register control circuit 1304 which controls the read and program reference levels based on count information held by the sector status registers 1302; an address buffer 1305 which receives an external address; a row decoder 1306, a column decoder 1307, and a column selector 1308 which are used to select memory cells in a sector based on an input external address; a sense amplifier/write amplifier 1309 which performs read operation and program operation; an I/O buffer 1310 which receives and outputs data from and to the outside; and a control circuit 1311 which controls the operation of these components.

Operation of the flash memory device thus configured will be described hereinafter. FIG. 14 is a flowchart showing a procedure of writing binary information into a flash memory cell having four setting regions for memory cell threshold voltages Vt.

Initially, when a data write command is externally received, the control circuit 1311 activates and outputs a data write command signal IPROG (low-level signal). Next, the programmed state of a sector selected based on input address signals XA(i) and YA(i) is read out as information SR(0) and SR(1) from the sector status registers 1302. In response to these two signals, the register control circuit 1304 outputs a reference level control signal SR(10).

The register control circuit 1304 determines whether or not the reference level control signal SR(10) indicates a logic 00 or a logic 01 (1401). If the determination is positive, the register control circuit 1304 outputs to the sector status registers 1302 a signal INC which is used to change (increase) the read and program reference levels to “01” or “10” to rewrite the contents of the sector status registers 1302 (1402).

On the other hand, the reference level generator circuit 1303 generates voltages VRREF and VPREF corresponding to the newly detected read and program reference levels, and performs program operation using the write amplifier 1309 (1403 and 1404).

On the other hand, when the reference level control signal SR(10) indicates a logic 10, an internal erase command IERASE is activated before data write, so that the selected sector is erased (1405). In this case, the register control circuit 1304 outputs a reset signal RST to the sector status registers 1302, which is then reset (1406).

When erase operation is completed, the reference level generator circuit 1303 generates voltages (VRREF and VRREF) corresponding to the read and program reference levels based on the reset reference level control signal SR(10), and then program operation is performed (1407 and 1408).

When data is written to the flash memory device, program operation is performed in sectors based on the procedure of FIG. 14. Therefore, different data write frequencies of the sectors would cause different contents of the sector status registers. The sector status registers are each a counter or a shift register which has a set/reset function so that the contents of the register are arbitrarily rewritten based on an external signal or an input command, and the initial contents are set prior to shipment.

### SUMMARY

In the flash memory device configuration of FIG. 13, the above operation can be performed while the sector status registers 1302 holds the number of data rewrite (reprogram) operations. However, when power supply is interrupted, information indicating the number of reprogram operations held in the sector status registers 1302 is erased. Therefore, when the flash memory device is turned on again, the contents of the status registers 1302 are indefinite, and therefore, an appropriate reference level cannot be set, so that data stored in a memory cell cannot be correctly read out.

When sectors having different numbers of reprogram operations are successively read out, reference levels also need to be switched at an address where switching of sectors occurs. Because reference levels are analog signals, it takes a time to stabilize a reference level when switching of reference levels occurs, which reduces or prevents high-speed read-out of the memory cell array 1301.

In the (m+1) program operation, erase operation is invariably performed. Therefore, in a system employing a conventional flash memory device, high-speed reprogram operation cannot be arbitrarily specified, and therefore, the benefit of speeding up of reprogram operation is not fully utilized.

The present disclosure describes implementations of a technique of speeding up reprogram operation, reducing or preventing the degradation of data hold capability caused by reprogram operation, and improving reprogram capability, and achieving intended operation without being affected by interruption or resumption of power supply, thereby reducing a circuit size and performing high-speed read operation.

An outline of representative examples of the present disclosure will be briefly described below.

A non-volatile semiconductor memory device according to a first aspect of the present disclosure includes, as major components, a memory cell array including a data storage area and a reprogram information storage area, a read circuit configured to determine a memory cell storage state of the memory cell array, a reprogram information holder configured to store data read from the reprogram information storage area, a plurality of read reference levels (read reference signals), and a selector configured to select a read reference level based on an output of the reprogram information holder.

In the non-volatile semiconductor memory device, by storing reprogram information in the non-volatile memory device, the reprogram information can be held without power supply. For example, when the power supply is turned on, reprogram information for each sector is read out, and the information is stored into the reprogram information holder. By setting a read reference level based on the information, data stored in memory cells of the data storage area can be read out.

A non-volatile semiconductor memory device according to a second aspect of the present disclosure includes, as major components, a memory cell array including a data storage area and a reprogram information storage area, a first read circuit configured to determine a memory cell storage state of the data storage area, a second read circuit configured to determine a memory cell storage state of the reprogram information storage area, a plurality of read reference levels (read reference signals), and a selector configured to select a read reference level based on an output of the second read circuit connected to the reprogram information storage area.

In the non-volatile semiconductor memory device, in each of read and reprogram operations, reprogram information for each sector is read out, and based on the information, a read reference level is set, whereby data stored in memory cells of the data storage area can be read out. Note that reprogram information is read out and a read reference level is set in every read or reprogram operation, resulting in a circuit configuration for low-speed read operation.

A non-volatile semiconductor memory device according to a third aspect of the present disclosure includes a memory cell array includes a data storage area including a plurality of memory cells having a plurality of possible storage states and a reprogram information storage area configured to store reprogram information, a first and a second read circuit configured to determine a memory cell storage state of the data storage area, a reprogram information holder configured to store data read from the reprogram information storage area, a first read reference level (first read reference signal) configured to be input to the first read circuit to determine a memory cell storage state of the data storage area in which a first storage state is stored as a first logic value and a second storage state is stored as a second logic value, and a second read reference level (second read reference signal) configured to be input to the second read circuit to determine a memory cell storage state of the data storage area in which the first and second storage states are stored as a first logic value and a third storage state is stored as a second logic value. One of outputs of the first and second read circuits is selected to output data read from at least one of the plurality of memory cells of the data storage area, based on an output of the reprogram information holder.

According to a fourth aspect of the present disclosure, in the non-volatile semiconductor memory device of any one of the first, second, and third aspects, the first state is an erase level state and the second state is a first program level state, and the third state is a second program level state which is different from the first program level state.

According to a fifth aspect of the present disclosure, in the non-volatile semiconductor memory device of any one of the first, second, and third aspects, the first logic value has a logic 1 and the second logic value has a logic 0.

According to a sixth aspect of the present disclosure, in the non-volatile semiconductor memory device of any one of the first, second, and third aspects, the first logic value has a logic 0 and the second logic value has a logic 1.

According to a seventh aspect of the present disclosure, in the non-volatile semiconductor memory device of any one of the first, second, and third aspects, the reprogram information holder includes a register configured to store data read from the reprogram information storage area.

According to an eighth aspect of the present disclosure, in the non-volatile semiconductor memory device of the first aspect, the read reference signal selector includes a switch configured to be controlled based on an output of the reprogram information holder.

According to a ninth aspect of the present disclosure, in the non-volatile semiconductor memory device of the second aspect, the read reference signal selector includes a switch configured to be controlled based on the output of the second read circuit.

According to a tenth aspect of the present disclosure, the non-volatile semiconductor memory device of the third aspect further includes a selector configured to select one of the outputs of the first and second read circuits based on the output of the reprogram information holder.

A non-volatile semiconductor memory device according to an eleventh aspect of the present disclosure includes a memory cell array including a data storage area including a plurality of memory cells having a plurality of possible storage states and a reprogram information storage area configured to store reprogram information, a read circuit configured to determine a memory cell storage state of the memory cell array, a signal terminal configured to receive an address signal configured to identify at least one of the plurality of memory cells of the data storage area and a control signal configured to control operation timing, a signal terminal configured to receive and output data, and receive a control command signal configured to set an operating mode, a control circuit configured to receive the control command signal and control internal operation, a signal terminal configured to output a state signal indicating whether the internal operation is being performed or is in a control command receive ready state, a plurality of read reference levels (read reference signals) configured to read a memory cell storage state of the data storage area, and a read reference signal selector configured to selectively output the plurality of read reference signals to the read circuit. The non-volatile semiconductor memory device, when receiving an erase command as the control command signal, selectively switches the plurality of read reference signals, and outputs the state signal indicating the control command receive ready state.

A non-volatile semiconductor memory device according to a twelfth aspect of the present disclosure includes, as major components, a memory cell array including a data storage area and a reprogram information storage area, a plurality of read circuits configured to determine a memory cell storage state of the data storage area, a reprogram information holder configured to store data read from the reprogram information storage area, and a plurality of read reference levels (read reference signals). The non-volatile semiconductor memory device, when receiving an erase command as the control command signal, selectively switches the plurality of read circuits, and outputs the state signal indicating the control command receive ready state.

In the non-volatile semiconductor memory device, for example, when the power supply is turned on, reprogram information for each sector is read out, the information is stored into the reprogram information holder, and based on the information, the outputs of the read circuits are selected, whereby data stored in memory cells of the data storage area can be read out. Therefore, it is not necessary to set a read reference level, resulting in a circuit configuration for high-speed read operation.

A signal processing system according to a thirteenth aspect of the present disclosure includes, as major components, a non-volatile semiconductor memory device and a processor. The non-volatile semiconductor memory device includes a memory cell array including a data storage area and a reprogram information storage area, a read circuit configured to determine a memory cell storage state of the data storage area, a signal terminal configured to receive an address signal and a control signal, a signal terminal configured to receive a control command signal configured to receive and output data, and set an operating mode, a control circuit, a signal terminal configured to output a state signal indicating internal operation is being performed or is in a control command receive ready state, a plurality of read reference levels (read reference signals), and a read reference signal selector configured to selectively output the plurality of read reference signals to the read circuit. The non-volatile semiconductor memory device, when receiving an erase command as the control command signal, selectively switches the plurality of read reference signals, and outputs the state signal indicating the control command receive ready state. The processor includes a signal terminal configured to output the address signal and the control signal to the non-volatile semiconductor memory device, a signal terminal configured to receive and output data, and output the control command signal, and a signal terminal configured to receive the state signal. The processor outputs the erase command to the non-volatile semiconductor memory device, reads the state signal of the non-volatile semiconductor memory device, and determines whether or not erase operation with respect to the non-volatile semiconductor memory device has been completed.

In the signal processing system, the erase operation with respect to the non-volatile semiconductor memory device is mostly completed by changing the read reference levels. Therefore, immediately after outputting an erase command to the non-volatile semiconductor memory device, the processor can read the state signal indicating that the erase operation has been completed and can be ready to perform the next operation.

A signal processing system according to a fourteenth aspect of the present disclosure includes a non-volatile semiconductor memory device and a processor. The non-volatile semiconductor memory device includes a memory cell array including a data storage area including a plurality of memory cells having a plurality of possible storage states and a reprogram information storage area configured to store reprogram information, a plurality of read reference levels (read reference signals) configured to read a memory cell storage state of the data storage area, a plurality of read circuits configured to receive the plurality of read reference signals to determine the memory cell storage state of the data storage area, a signal terminal configured to receive an address signal configured to identify at least one of the plurality of memory cells of the data storage area and a control signal configured to control operation timing; a signal terminal configured to receive and output data, and receive a control command signal configured to set an operating mode, a control circuit configured to receive the control command signal and control internal operation, and a signal terminal configured to output a state signal indicating whether the internal operation is being performed or is in a control command receive ready state. The non-volatile semiconductor memory device, when receiving an erase command as the control command signal, selectively switches the plurality of read circuits, and outputs the state signal indicating the control command receive ready state. The processor includes a signal terminal configured to output the address signal and the control signal to the non-volatile semiconductor memory device, a signal terminal configured to receive and output data, and output the control command signal, and a signal terminal configured to receive the state signal. The processor outputs the erase command to the non-volatile semiconductor memory device, reads the state signal of the non-volatile semiconductor memory device, and determines whether or not erase operation with respect to the non-volatile semiconductor memory device has been completed.

According to a fifteenth aspect of the present disclosure, in the non-volatile semiconductor memory device or the signal processing system of any one of the first to third and eleventh to fourteenth aspects, the plurality of storage states of each memory cell are a plurality of threshold values.

According to a sixteenth aspect of the present disclosure, in the non-volatile semiconductor memory device or the signal processing system of any one of the first to third and eleventh to fourteenth aspects, the plurality of storage states of each memory cell are a plurality of resistance values.

According to a seventeenth aspect of the present disclosure, in the non-volatile semiconductor memory device or the signal processing system of any one of the first to third and eleventh to fourteenth aspects, the read reference signal indicates a read reference current value.

According to an eighteenth aspect of the present disclosure, in the signal processing system of the thirteenth or fourteenth aspect, the state signal is a ready/busy signal which indicates whether the non-volatile semiconductor memory device is operating or is ready to receive a control command, and is output to a specific signal terminal.

According to a nineteenth aspect of the present disclosure, in the signal processing system of the thirteenth or fourteenth aspect, the state signal is a data polling signal which is output, to a data terminal, as a signal indicating whether the non-volatile semiconductor memory device is operating or has completed operation.

A method for controlling a signal processing system in reprogram operation according to a twentieth aspect of the present disclosure has the following major features. In the signal processing system, a memory cell array is divided into a plurality of erase units. A processor reads reprogram information of a first erase unit in a non-volatile semiconductor memory device, and if erase operation is not completed by switching read reference signals, outputs an erase command with respect to a second erase unit which is different from the first erase unit.

In the method for controlling the signal processing system in reprogram operation, if the erase operation of the non-volatile semiconductor memory device is not completed by switching the read reference signals, i.e., it is necessary to change storage states of memory cells, an erase command is output with respect to a different erase unit, whereby high-speed reprogram operation can invariably be achieved.

A method for controlling a signal processing system according to a twenty-first aspect of the present disclosure is a method for controlling a signal processing system including a non-volatile semiconductor memory device and a processor. The non-volatile semiconductor memory device includes a memory cell array including a data storage area including a plurality of memory cells having a plurality of possible storage states and a reprogram information storage area configured to store reprogram information, where the memory cell array is divided into a plurality of erase units, a plurality of read reference levels (read reference signals) configured to read data stored in at least one of the plurality of memory cells, a plurality of read circuits configured to receive the plurality of read reference signals to determine a state of at least one of the plurality of memory cells, a signal terminal configured to receive an address signal configured to identify at least one of the plurality of memory cells, and a control signal configured to control operation timing, a signal terminal configured to receive and output data, and receive a control command signal configured to set an operating mode, a control circuit configured to receive the control command signal and control internal operation, a signal terminal configured to output a state signal indicating whether the internal operation is being performed or is in a control command receive ready state, and a read reference signal selector configured to selectively output the plurality of read reference signals to the plurality of read circuits. The processor includes a signal terminal configured to output the address signal and the control signal to the non-volatile semiconductor memory device, a signal terminal configured to receive and output data, and output the control command signal, and a signal terminal configured to receive the state signal. The non-volatile semiconductor memory device, when receiving an erase command as the control command signal, selectively switches the plurality of read circuits, and outputs the state signal indicating the control command receive ready state. The processor reads reprogram information of a first erase unit from the non-volatile semiconductor memory device, and if it is necessary to change a storage state of at least one of the plurality of memory cells in the first erase unit when outputting an erase command, outputs the erase command with respect to a second erase unit which is different from the first erase unit.

According to a twenty-second aspect of the present disclosure, in the method of the twentieth or twenty-first aspect, the processor, after outputting a program command with respect to the second erase unit, reads the state signal of the non-volatile semiconductor memory device, and if the state signal indicates the control command receive ready state, erases the first erase unit into an initial state.

According to a twenty-third aspect of the present disclosure, in the method of the twentieth or twenty-first aspect, the plurality of erase units are N different erase units, where N is two or more, and the processor outputs a program command with respect to one of the N erase units.

A method for reprogramming a non-volatile semiconductor memory device according to a twenty-fourth aspect of the present disclosure is provided. The non-volatile semiconductor memory device includes a memory cell array including a data storage area including a plurality of memory cells having a plurality of possible storage states and a reprogram information storage area configured to store reprogram information, a read circuit configured to determine a memory cell storage state of the data storage area, and a plurality of read reference levels (read reference signals). Read operation is performed using the plurality of read reference signals. When reprogram operation is performed in a first data state in which a first logic value or a second logic value is written in the data storage area, then if information in the reprogram information storage area indicates that the number of reprogram operations is less than a predetermined value, reprogram information obtained by adding one to the number of reprogram operations is written to the reprogram information storage area, and based on the information indicating the number of reprogram operations stored in the reprogram information storage area, the plurality of read reference signals are selected, and data is written to a second data state different from the first data state, or then if the information in the reprogram information storage area indicates the predetermined value, the data storage area and the reprogram information storage area are erased, and based on the information indicating the number of reprogram operations stored in the reprogram information storage area, one is selected from the plurality of read reference signals, and with reference to the selected read reference signal, data is written into a second data state which is different from the first data state. The predetermined value is set in association with the number of the plurality of possible read reference signals.

A method for reprogramming a non-volatile semiconductor memory device according to a twenty-fifth aspect of the present invention is provided. The non-volatile semiconductor memory device includes a memory cell array including a data storage area including a plurality of memory cells having a plurality of possible storage states and a reprogram information storage area configured to store reprogram information, a high-speed program mode signal terminal, a read circuit configured to determine a memory cell storage state of the data storage area, and a plurality of read reference levels (read reference signals). Read operation is performed using the plurality of read reference signals. When reprogram operation is performed in a first data state in which a first logic value or a second logic value is written in the data storage area, then if information in the reprogram information storage area is less than a first setting value and the high-speed program mode signal terminal is valid, reprogram information obtained by adding one to the number of reprogram operations is written to the reprogram information storage area, and based on the information indicating the number of reprogram operations stored in the reprogram information storage area, one is selected from the plurality of read reference signals, and with reference to the selected read reference signal, data is written into a second data state different from the first data state, or then if the information in the reprogram information storage area is not less than the first setting value or the high-speed program mode signal terminal is invalid, then if the information in the reprogram information storage area is less than a second setting value, reprogram information obtained by adding one to the number of reprogram operations is written to the reprogram information storage area, and based on the information indicating the number of reprogram operations stored in the reprogram information storage area, one is selected from the plurality of read reference signals, and with reference to the selected read reference signal, data is written into the second data state different from the first data state, or then if the information in the reprogram information storage area is the second setting value, the data storage area and the reprogram information storage area are erased, and based on the information indicating the number of reprogram operations stored in the reprogram information storage area, one is selected from the plurality of read reference signals, and with reference to the selected read reference signal, data is written into the second data state different from the first data state. The first and second predetermined values are set in association with the plurality of possible read reference signals, and the first predetermined value is greater than the second predetermined value.

According to a twenty-sixth aspect of the present disclosure, in the method of the twenty-fourth or twenty-fifth aspect, the plurality of read reference signals are M different read reference signals, where M is two or more. The selection of the plurality of read reference signals is selection of a specific one from the M read reference signals. The data states are M different data states, where M is two or more. In the program operation, data is written into one of the M data states.

As described above, according to the non-volatile semiconductor memory device of the present disclosure, the reprogram speed can be increased, and the degradation of the data hold capability due to reprogram operation can be reduced or prevented. In addition, the reprogram capability can be improved, intended operation can be achieved without being affected by interruption or resumption of power supply, a circuit size can be reduced, and high-speed read operation can be achieved.

### BRIEF DESCRIPTION OF THE DRAWINGS

FIG. 1 is a diagram showing a configuration of a non-volatile semiconductor memory device according to a first embodiment of the present disclosure.

FIG. 2 is a diagram showing a specific example circuit configuration of a reference level generator circuit, a reference level switch circuit, and a reprogram information holder circuit of FIG. 1.

FIG. 3 is a diagram showing the relationship between the number of reprogram operations, and reprogram information and reference levels.

FIG. 4 is a diagram showing an example configuration of a non-volatile semiconductor memory device according to a second embodiment of the present disclosure.

FIG. 5 is a diagram showing an example configuration of a non-volatile semiconductor memory device according to a third embodiment of the present disclosure.

FIG. 6 is a diagram showing a specific example circuit configuration of a read block of FIG. 5.

FIG. 7 is a diagram showing a specific example circuit configuration of a control circuit of FIGS. 1, 4, and 5.

FIG. 8 is a diagram showing example timings of signals which are input and output when an erase command is issued.

FIG. 9 is a diagram showing another example timings of signals which are input and output when an erase command is issued.

FIG. 10 is a diagram showing distributions of memory cell threshold voltages Vt in a conventional non-volatile semiconductor memory device.

FIG. 11 is a diagram showing setting regions for memory cell threshold voltages Vt in a conventional non-volatile semiconductor memory device.

FIG. 12 is a diagram showing data states in a conventional non-volatile semiconductor memory device which stores binary information.

FIG. 13 is a block diagram showing a circuit configuration of a conventional non-volatile semiconductor memory device.

FIG. 14 is a flowchart showing a procedure of writing binary information to a conventional non-volatile semiconductor memory device.

FIG. 15 is a block diagram showing a configuration of a signal processing system according to a fourth embodiment of the present disclosure.

FIG. 16 is a timing diagram of erase operation in which the thresholds of memory cells in the signal processing system of the fourth embodiment are changed.

FIG. 17 a timing diagram of pseudo-erase operation in which the thresholds of memory cells in the signal processing system of the fourth embodiment are not changed.

FIG. 18 is a flowchart showing a method for controlling a signal processing system according to a fifth embodiment of the present disclosure in reprogram operation.

FIG. 19 is a flowchart showing an example method for reprogramming a non-volatile semiconductor memory device according to a sixth embodiment of the present disclosure.

FIG. 20 is a diagram showing distributions of memory cell threshold voltages Vt in a flash memory device for describing transition of a memory array in a reprogram flow of the non-volatile semiconductor memory device of the sixth embodiment.

FIG. 21 is a flowchart showing an example method for reprogramming a non-volatile semiconductor memory device according to a seventh embodiment of the present disclosure.

FIG. 22 is a diagram showing distributions of memory cell threshold voltages Vt in a flash memory device for describing transition of a memory array in a reprogram flow of the non-volatile semiconductor memory device of the seventh embodiment.

### DETAILED DESCRIPTION

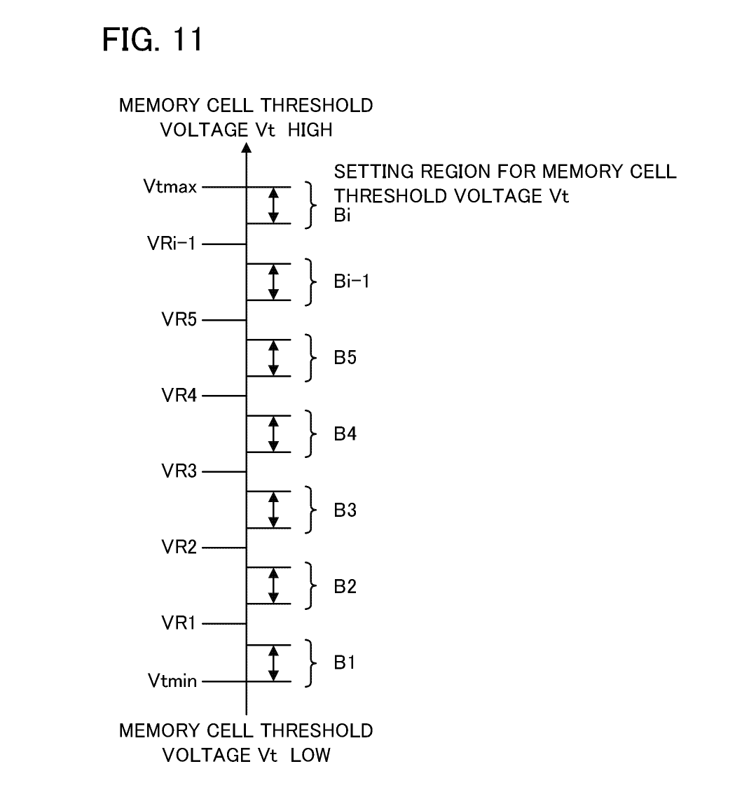

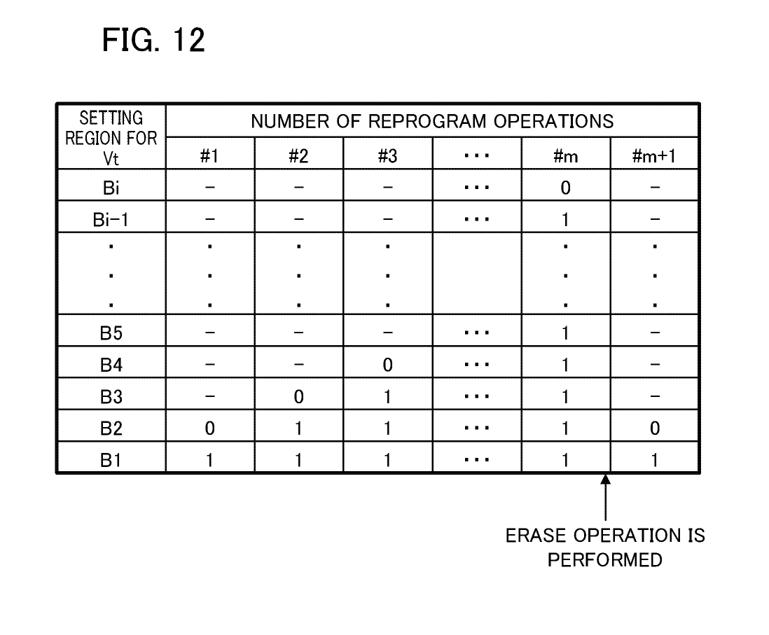

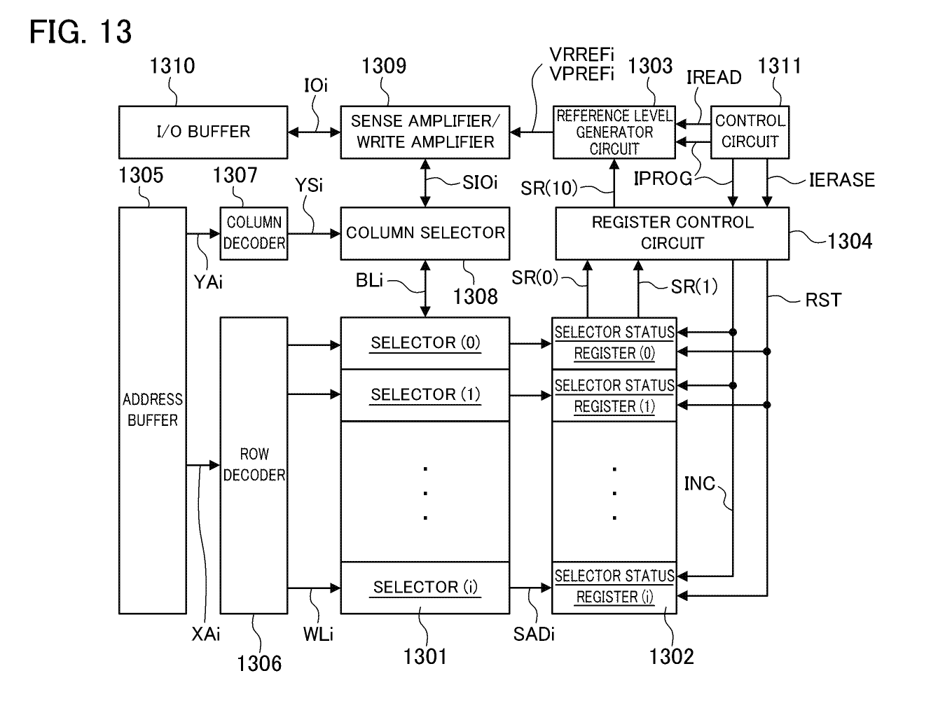

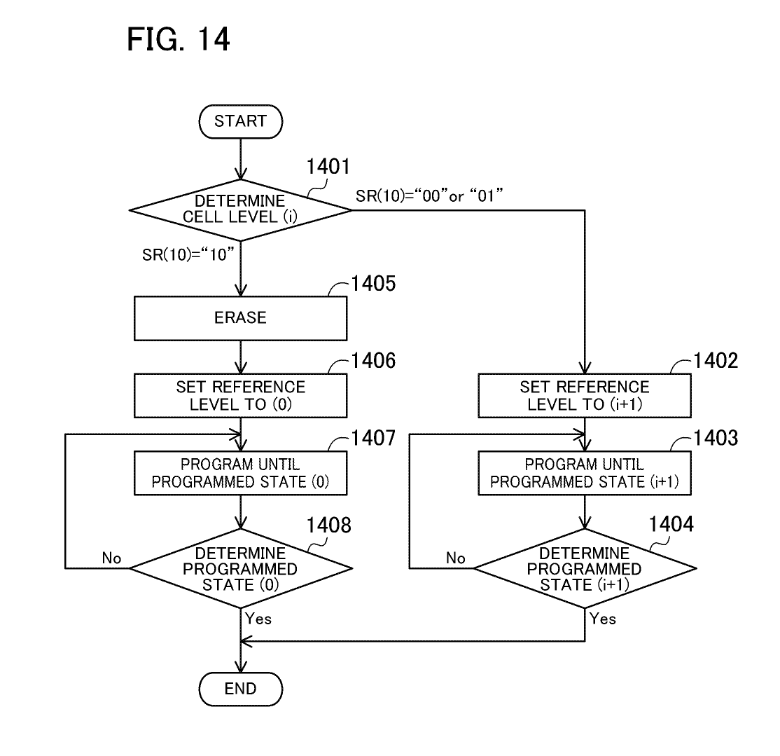

The present disclosure employs a plurality of setting regions for memory cell threshold voltages Vt as shown in FIG. 11.

Embodiments of the present disclosure will be described hereinafter with reference to the accompanying drawings. Note that the embodiments are only for illustrative purposes, and the present disclosure is not limited to the embodiments.

### First Embodiment

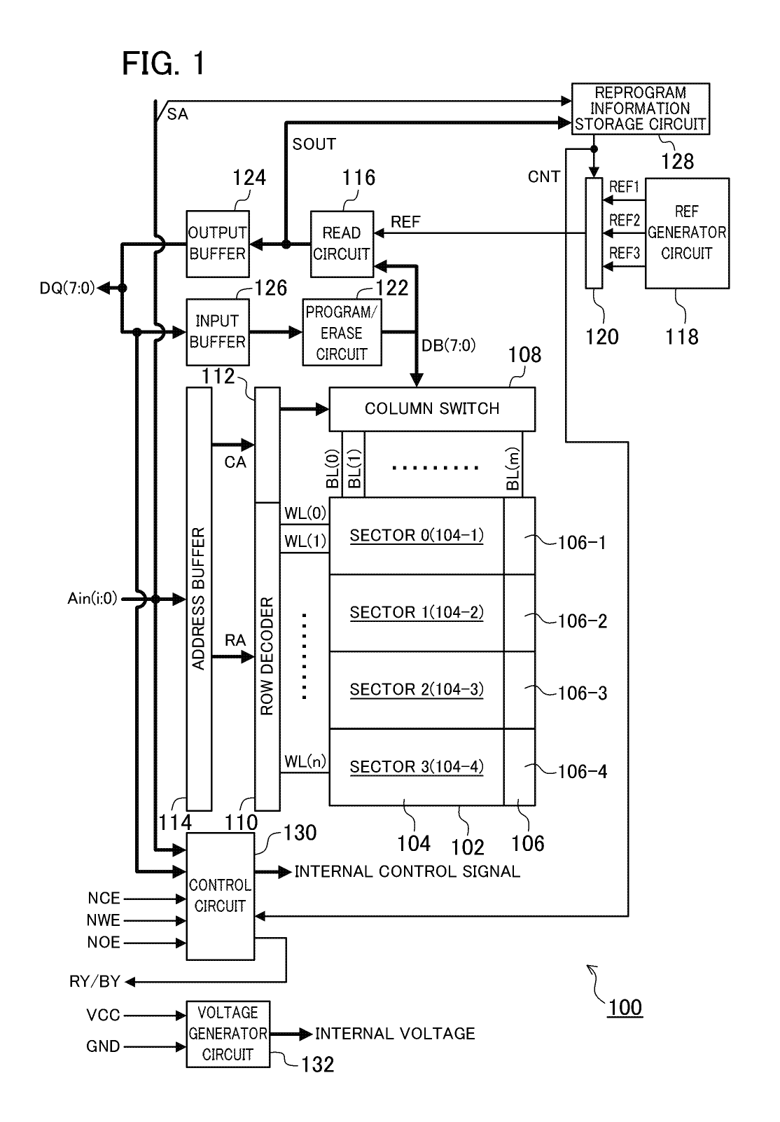

FIG. 1 is a diagram showing a configuration of a flash memory device 100 according to a first embodiment of the present disclosure. In FIG. 1, the bit width of data input/output is 8 bits, and four memory cell threshold setting regions represented by a logic 11, a logic 01, a logic 10, and a logic 00 are provided. An outline of the configuration and operation of the flash memory device of this embodiment will be firstly described with reference to the drawings.

The flash memory device 100 of FIG. 1 includes a memory cell array 102 for storing data. The memory cell array 102 includes a data storage area 104 including a plurality of sectors (erase units) 0 (104-1), 1 (104-2), 2 (104-3), and 3 (104-4) which can be erased separately, and a reprogram information storage area 106 including storage areas 106-1, 106-2, 106-3, and 106-4 corresponding to the respective erase units. In the memory cell array 102, flash memory cells are provided at intersections between word lines WL(0)-WL(n) and bit lines BL(0)-BL(m), i.e., are arranged in a grid pattern. The memory cells in the data storage area 104 and the memory cells in the reprogram information storage area 106 are connected to the same word lines. Therefore, by selecting a word line, memory cells connected to the word line can be selected together.

A row decoder 110 receives a row address RA of address input signals input to an address input terminal Ain(i:0) via an address buffer 114, and supplies a required potential to the word lines WL(0)-WL(n) of the memory cell array 102, depending on each operating mode of the flash memory device 100.

In a read mode and a program mode of the flash memory device 100, the row decoder 110 decodes the row address RA to output a signal for selecting one of the word lines. The row decoder 110 outputs a potential of about 3 V in the read mode and a potential of about 10 V in the program mode.

In erase operation with respect to the flash memory device 100 in which the thresholds of memory cells are initialized, word lines corresponding to a sector to be selected are selected at a time, and a potential of about −8 V is applied to the word lines.

The bit lines BL(0)-BL(m) of the memory cell array 102 are connected to a column switch 108. Moreover, eight designated bit lines are selectively connected via the column switch 108 to a data bus DB(7:0). The column switch 108 receives a select signal from a column decoder 112. The column decoder 112 also receives a column address CA via the address buffer 114, and decodes the column address CA to output a corresponding bit line select signal. Based on the bit line select signal from the column decoder 112, eight bit lines are selectively connected to the data bus DB(7:0).

A program/erase circuit 122 is connected to the data bus DB(7:0). The program/erase circuit 122 includes eight program circuits corresponding to the respective data buses of the data bus DB(7:0). In the program mode of the flash memory device 100, write data input via an input buffer 126 from a data input/output terminal DQ(7:0) is written via the data bus DB(7:0) to eight selected memory cells by applying a program potential to eight selected bit lines of the memory cell array 102. In this case, a program signal which is applied to the eight selected bit lines has a potential of about +6 V with respect to a bit line which is used for program operation, and a ground potential with respect to a bit line which is not used for program operation.

In erase operation with respect to the flash memory device 100 in which the thresholds of memory cells are set to the initialized state (i.e., the logic 11), the column switch 108 is controlled to select all the bit lines BL(0)-BL(m), and the program/erase circuit 122 applies a potential of about +6 V to all the bit lines BL(0)-BL(m).

The data bus DB(7:0) is also connected to a read circuit 116. The read circuit 116 includes eight read circuits corresponding to the respective data buses of the data bus DB(7:0). The read circuit 116 is used to perform, with respect to selected memory cells of the memory cell array 102, data read in the read mode, data read for program verification in the program mode, and data read for erase verification in the erase mode.

The read circuit 116 performs data read as follows. The read circuit 116 checks data which is output from the eight selected memory cells of the memory cell array 102 via the eight bit lines and the data bus DB(7:0), using a read reference level REF output from a reference level switch circuit 120, and outputs the result of the check via an output buffer 124 to the data input/output terminal DQ(7:0). In this case, the read circuit 116 applies a voltage of about +1 V to the selected eight bit lines of the memory cell array 102.

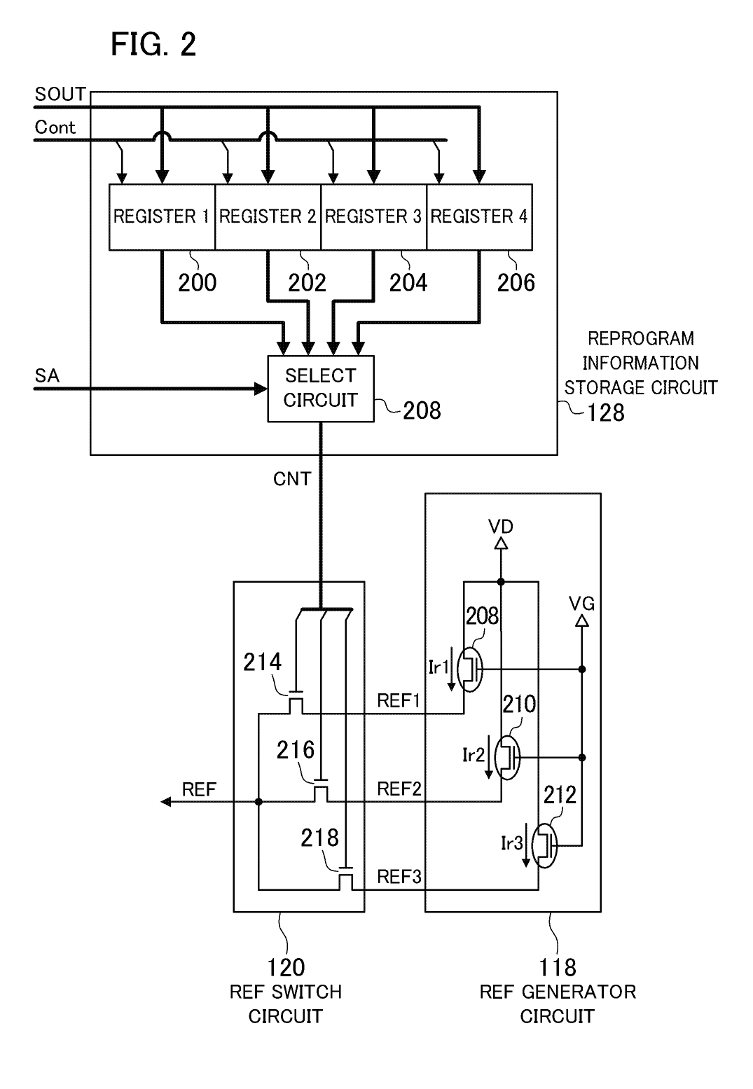

Here, FIG. 2 shows a specific example circuit configuration of a reference level generator circuit (reference signal generator circuit) 118, a reference level switch circuit (read reference signal selector) 120, and a reprogram information holder circuit (reprogram information holder) 128, which constitute a circuit block for setting the read reference level (read reference signal) REF. The reference level generator circuit 118 includes memory cells 208, 210, and 212 which have the same structure as that of the flash memory cells of the memory cell array 102. The memory cells 208, 210, and 212 have different threshold values. The drain terminals of the memory cells 208, 210, and 212 are connected together, and the gate terminals of the memory cells 208, 210, and 212 are connected together. The drain and gate terminals of the memory cells 208, 210, and 212 are connected to the same drain potential VD and gate potential VG as those of the memory cells of the memory cell array 102. Therefore, memory cell currents Ir1, Ir2, and Ir3 which are reference levels (reference signals) are generated and output as reference levels (reference signals) REF1, REF2, and REF3 for determining the four memory cell threshold setting regions represented by the logic 11, the logic 01, the logic 10, and the logic 00.

The reference levels REF1, REF2, and REF3 can be set to appropriate values for read operation, program verify operation, and erase verify operation by changing the gate potentials VG of the memory cells 208, 210 and 212 during the respective operations. Alternatively, different value levels may be provided for different operations (i.e., read, program verify, and erase verify operations), and the value levels may be appropriately switched and set, depending on each operation. In either case, the memory cell array 102 is read in a similar manner. In the description of this embodiment, only reference levels for read operation will be described. In the case of read reference levels, the reference levels REF1, REF2, and REF3 are intermediate levels between the four memory cell threshold setting regions represented by the logic 11, the logic 01, the logic 10, and the logic 00.

The reprogram information holder circuit 128 includes registers 1 (200) to 4 (206) which store the same information as that which is stored in the reprogram information storage areas 106-1 to 106-4 corresponding to the sectors (104-1 to 104-4) of the memory cell array 102, and a select circuit 208. The reprogram information holder circuit 128 uses the select circuit 208 to select the output of a register corresponding to a sector address SA of address input signals supplied to the address input terminal Ain(i:0), and output the output of the selected register as reprogram information CNT.

The reference level switch circuit 120, which includes transistors 214, 216, and 218, is a switch which is controlled based on the reprogram information CNT output from the reprogram information holder circuit 128. The reference level switch circuit 120 selects one of the reference levels REF1, REF2, and REF3 generated by the reference level generator circuit 118, and outputs the selected reference level as a reference level REF to the read circuit 116.

The flash memory device 100 of this embodiment further includes a control circuit 130 which generates an internal control signal for controlling the operation of each circuit block based on control signals received via external terminals NCE, NOE, and NWE and the operating mode of the flash memory device 100 set by an operation command input via the address input terminal Ain(i:0) and the data input/output terminal DQ(7:0), and a ready/busy signal (hereinafter referred to as an RY/BY signal) which is a state signal indicating the internal operating state of the flash memory device 100, i.e., whether the flash memory device 100 is operating or is ready to receive an operation command.

The control circuit 130 receives an operation command (program or erase operation command), and uses a specific bit of the data input/output terminal DQ(7:0) to output a state signal indicating whether the operation is being performed or has been completed.

The flash memory device 100 further includes a voltage generator circuit 132 for generating, based on a power supply voltage VCC, internal voltages which are required in the operating modes.

Here, reprogram operation with respect to the data storage area 104 of the memory cell array 102 will be described.

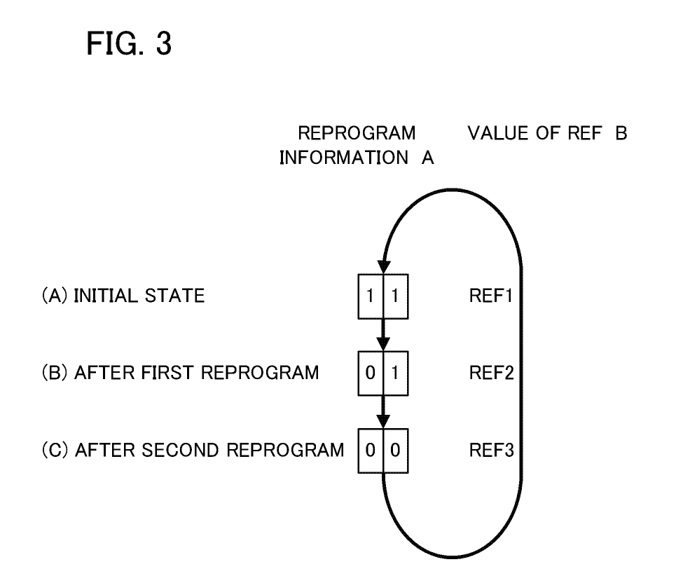

When data is rewritten, a target sector is erased before data write. In erase operation, reprogram information (A) shown in FIG. 3 is written to the reprogram information storage area 106 corresponding to the sector to be reprogrammed and the registers 200-206 of the reprogram information holder circuit 128, based on a control signal from the control circuit 130. A value (B) of the reference level REF selected based on the reprogram information written in the registers 200-206 is also shown in FIG. 3.

In this embodiment, because the four memory cell threshold setting regions represented by the logic 11, the logic 01, the logic 10, and the logic 00 are used, a two-bit signal is used as reprogram information. Alternatively, a larger number of threshold setting regions can be used by increasing the number of bits of reprogram information.

A portion (a) of FIG. 3 indicates a case where memory cells are set to the initial state which is the threshold region of the logic 11 (hereinafter referred to as erase operation). When REF1 is selected as the reference level REF, data read from memory cells whose thresholds are set in the logic 11 are all “1.” In this state, by writing data to the data storage area 104 using the threshold region of the logic 01, reprogram operation is completed. The written data is determined by the read circuit 116 using the reference level REF1.

In the state in which data is written using the threshold region of the logic 01, when erase operation for rewriting data is performed, reprogram information shown in a portion (b) of FIG. 3 is written to the reprogram information storage area 106 and the registers 200-206 of the reprogram information holder circuit 128. Therefore, the value of the reprogram information CNT of the select circuit 208 is changed, and the reference level switch circuit 120 selects and outputs the reference level REF2 to the read circuit 116. As a result, all portions of stored information of memory cells set in the threshold regions of the logic 11 and the logic 01 are read as data “1,” which is a state (hereinafter referred to as pseudo-erase operation) equivalent to that which is obtained when erase operation is performed. In this state, data is written to the data storage area 104 using the threshold region of the logic 10, and therefore, the reprogram operation is completed. The value of written data can be determined by the read circuit 116 using the reference level REF2.

In the state in which data is written using the threshold region of the logic 10, reprogram operation is performed in a manner similar to that of the above operation. Specifically, reprogram information to the reprogram information storage area 106 and the registers 200-206 of the reprogram information holder circuit 128 is changed without changing the thresholds of memory cells, to change reference levels to be selected (pseudo-erase operation), and thereafter, data is written to the data storage area 104 using the threshold region of the logic 00, whereby reprogram operation is achieved.

In the state in which data is written using the threshold region of the logic 00, reprogram operation is performed as follows. By performing erase operation accompanied by changing of the thresholds of memory cells, the memory cells are set to the initial state, i.e., the threshold region of the logic 11, and the reprogram information storage area 106 and the registers 200-206 of the reprogram information holder circuit 128 are set to the state of the portion (a) of FIG. 3. Thereafter, the above operation is repeated.

Thus, by using the configuration of the embodiment of FIG. 1, reprogram information of FIG. 3 is written to the registers 200-206 of the reprogram information holder circuit 128 when erase operation is performed, whereby the erase operation can be achieved without changing the thresholds. However, when power supply to the flash memory device 100 is interrupted, the reprogram information written in the registers 200-206 is erased. Therefore, in order to select an appropriate reference level for correctly reading out written data, the contents of the registers 200-206 need to be restored after the power supply is turned on again.

Therefore, in the configuration of FIG. 1, when the power supply is turned on, stored information of the reprogram information storage area 106 of the memory cell array 102 is successively read out by the read circuit 116, and is then written to the registers 200-206, by a control performed by the control circuit 130. Reprogram information is written to the reprogram information storage area 106 using the threshold region 11 and the threshold region 00. Even if any one of RFE1, RFE2, and RFE3 is used as a reference level, data can be read from the reprogram information storage area 106 when the power supply is turned on.

In FIG. 1, in order to achieve pseudo-erase operation which is not accompanied by changing of the thresholds, reprogram information is stored in the reprogram information storage area 106 of the memory cell array 102 and the reprogram information holder circuit 128. A simpler configuration which can perform similar operation will be described hereinafter.

### Second Embodiment

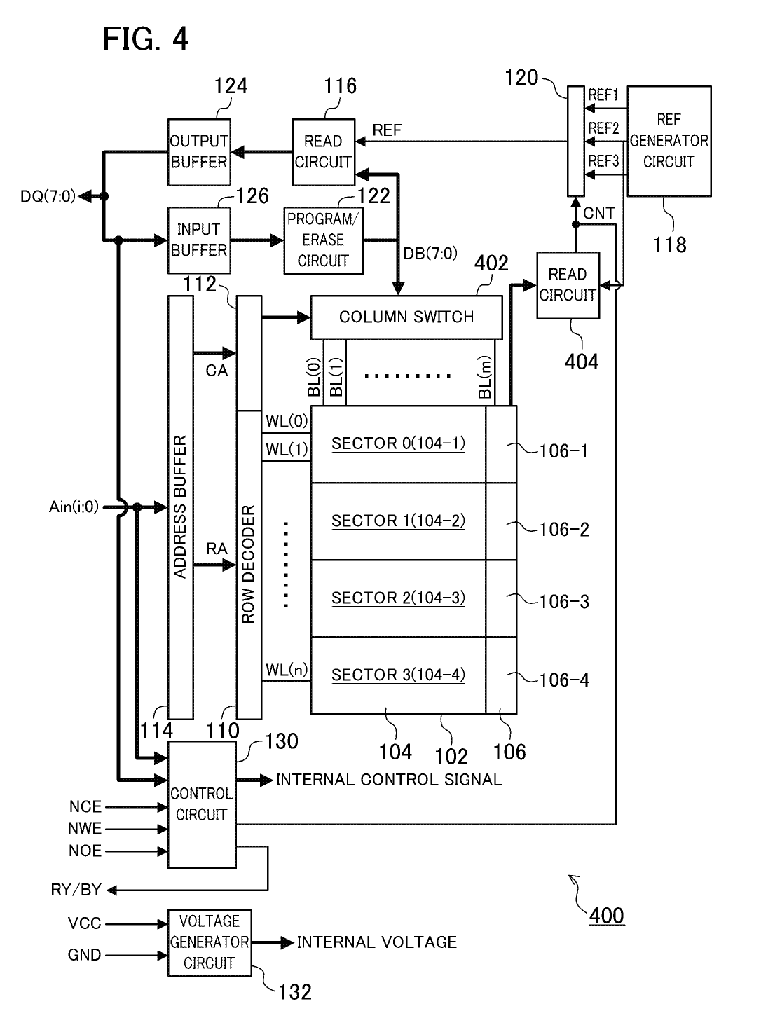

FIG. 4 is a diagram showing a configuration of a flash memory device 400 according to a second embodiment of the present disclosure. In FIG. 4, the same parts as those of FIG. 1 are indicated by the same reference characters.

The flash memory device 400 of FIG. 4 is different from the flash memory device 100 of FIG. 1 in that, in addition to the read circuit (first read circuit) 116, a read circuit (second read circuit) 404 is provided, and reprogram information stored in the reprogram information storage area 106 is read out by the second read circuit 404 without using a column switch 402, and is then input as reprogram information CNT to the reference level switch circuit 120, which is controlled based on the reprogram information CNT. In this case, the read circuit 404 determines the value of data using the reference level REF2 obtained from the reference level generator circuit 118.

As is similar to FIG. 1, data is written to the reprogram information storage area 106 using the threshold regions of the logic 11 and the logic 00, and data is read out using the reference level REF2, whereby the value of data can be correctly determined.

In program and erase operations, the column switch 402 is operated in a manner similar to that of FIG. 1. Specifically, based on a select signal from the column decoder 112, the data bus DB(7:0) is selectively connected to the bit lines BL(0)-BL(m) of the data storage area 104 and the reprogram information storage area 106.

Reprogram operation is performed with respect to the data storage area 104 in a manner similar to that of FIG. 1. Specifically, when erase operation is performed with respect to the data storage area 104, the data of FIG. 3 is written to the reprogram information storage area 106.

Data is read from the data storage area 104 as follows. Initially, the read circuit 404 is used to read stored information from the reprogram information storage area 106, and the reprogram information CNT is input to the reference level switch circuit 120.

As a result, when data is read from the data storage area 104, the reference level switch circuit 120 selects a reference level corresponding to the reprogrammed state of a sector to be read, and outputs the reference level to the read circuit 116, whereby the value of data can be determined using an appropriate reference level corresponding to the reprogrammed state.

The example configuration of FIG. 4 is useful for memories which require a relatively low read speed, such as NAND flash memory.

A reference level is selected using reprogram information stored in the reprogram information storage area 106 of the memory cell array 102. Therefore, data is not erased even when the power supply to the flash memory device 400 is interrupted.

In the example configurations of FIGS. 1 and 2, a reference level is selected by the reference level switch circuit 120 based on the reprogram information CNT. Therefore, if sectors in the memory cell array 102 which have different reprogrammed states are successively read out, reference levels are switched when sector addresses are switched. Because reference levels are analog signals, it takes a time to stabilize a reference level when switching of reference levels is performed, which reduces or prevents high-speed read-out of the data storage area 104. A technique of reading the data storage area 104 at high speed will be described hereinafter.

### Third Embodiment

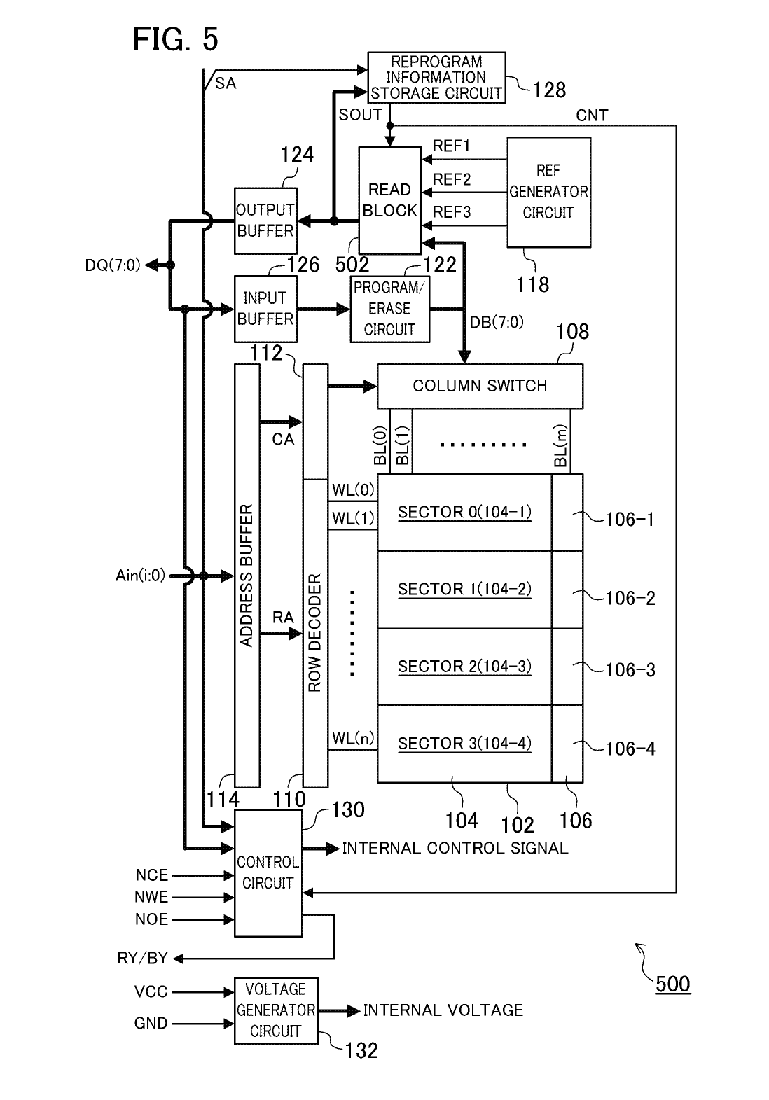

FIG. 5 is a diagram showing a configuration of a flash memory device 500 according to a third embodiment of the present disclosure. In FIG. 5, the same parts as those of FIG. 1 are indicated by the same reference characters.

The flash memory device 500 of FIG. 5 is different from the flash memory device 100 of FIG. 1 in that a read block 502 is connected to the data bus DB(7:0), and the outputs REF1, REF2, and REF3 of the reference level generator circuit 118 and the reprogram information CNT of the reprogram information holder circuit 128 are input to the read block 502.

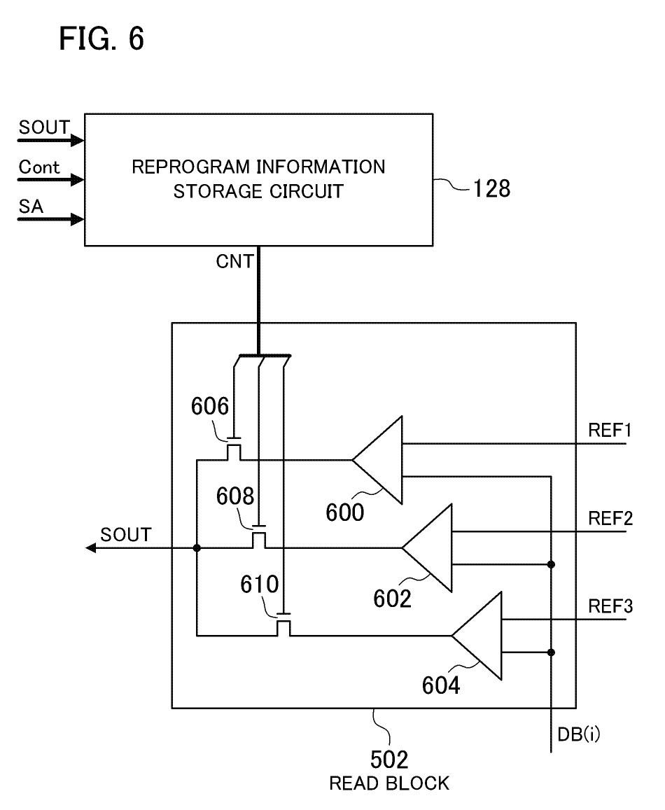

FIG. 6 shows a specific example circuit configuration of the read block 502. FIG. 6 shows a read block connected to a one-bit data bus DB(i) of the data bus DB(7:0). The read block includes read circuits 600, 602, and 604. The reference levels REF1, REF2, and REF3 are input to the read circuits 600, 602, and 604, respectively. The outputs of the read circuits 600, 602, and 604 are input to transistors 606, 608, and 610, respectively.

The transistors 606, 608, and 610 are driven based on the reprogram information CNT from the reprogram information holder circuit 128 to select one of the outputs of the read circuits 600, 602, and 604 and output the selected output as SOUT.

With the configuration of FIG. 5, when sectors in the reprogrammed state of the memory cell array 102 are successively read out, then if selected sectors are switched, the output of the read circuit 600, 602, or 604 which is used to determine the value of data based on a reference level corresponding to the reprogrammed state is selected based on the reprogram information CNT from the reprogram information holder circuit 128, and is then output as the read data SOUT. The outputs of the read circuits 600, 602, and 604 are logic value signals and can be quickly switched, and therefore, the data storage area 104 can be read at high speed.

Next, a specific example configuration of the control circuit 130 of FIGS. 1, 4, and 5, and the operation in the erase mode with respect to the flash memory device, will be described.

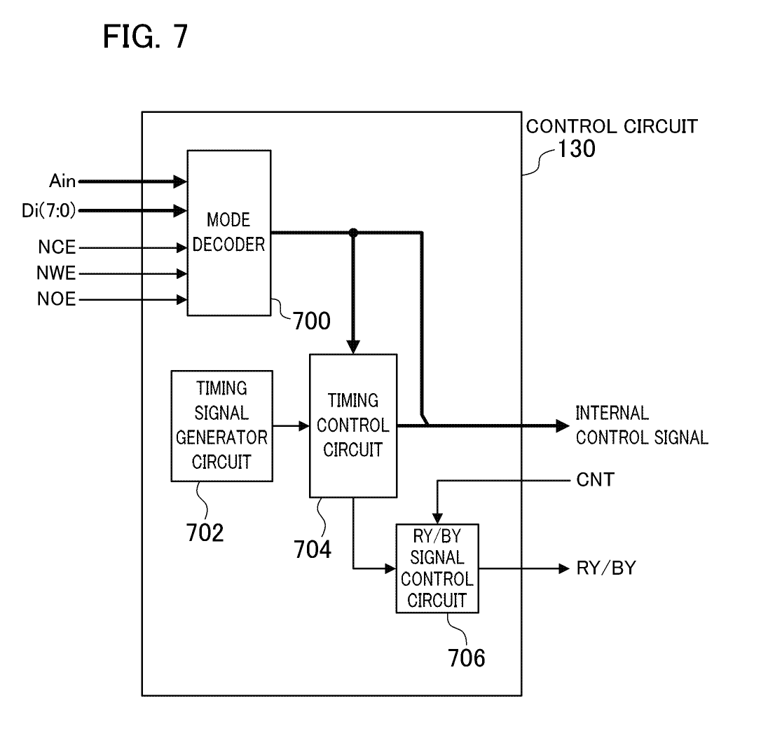

FIG. 7 shows a specific example configuration of the control circuit 130. The operating mode with respect to the flash memory device is determined using a mode decoder 700 based on an operation command input via the address input terminal Ain(i:0) and the data input/output terminal DQ(7:0) and the control signals NCE, NOE, and NWE.

A timing control circuit 704 receives signals from the mode decoder 700 and a timing signal generator circuit 702 (e.g., a clock etc.), and outputs a control signal which is used in combination with the output of the mode decoder 700 to control the inside of the flash memory device.

An RY/BY signal control circuit 706 determines, based on the value of the reprogram information CNT, whether the operation of the flash memory device performed when an erase command is received as an operation command for the flash memory device is erase operation in which memory cells are set to the initial state, i.e., the threshold region of the logic 11, or pseudo-erase operation in which reprogram information is written to the reprogram information storage area 106 and the registers 200-206 of the reprogram information holder circuit 128, and controls the output timing of an RY/BY signal which is a state signal indicating the internal operating state of the flash memory device, i.e., whether the flash memory device is operating or is ready to receive an operation command.

Similarly, the control circuit 130 controls a signal which indicates whether the operation is being performed or has been completed and is output to the data input/output terminal DQ(7:0), depending on whether the operation is erase operation or pseudo-erase operation.

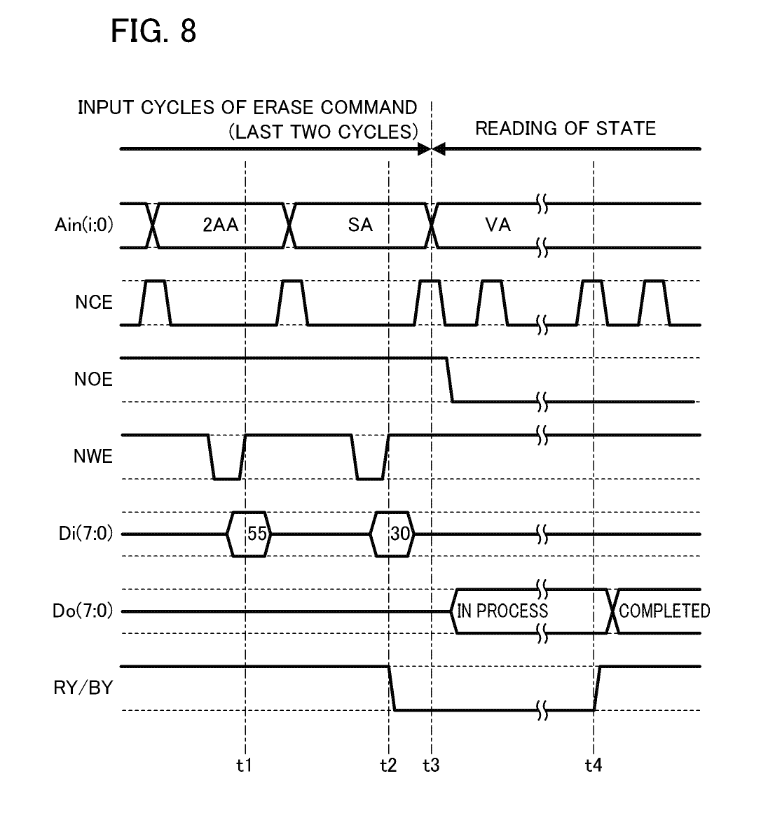

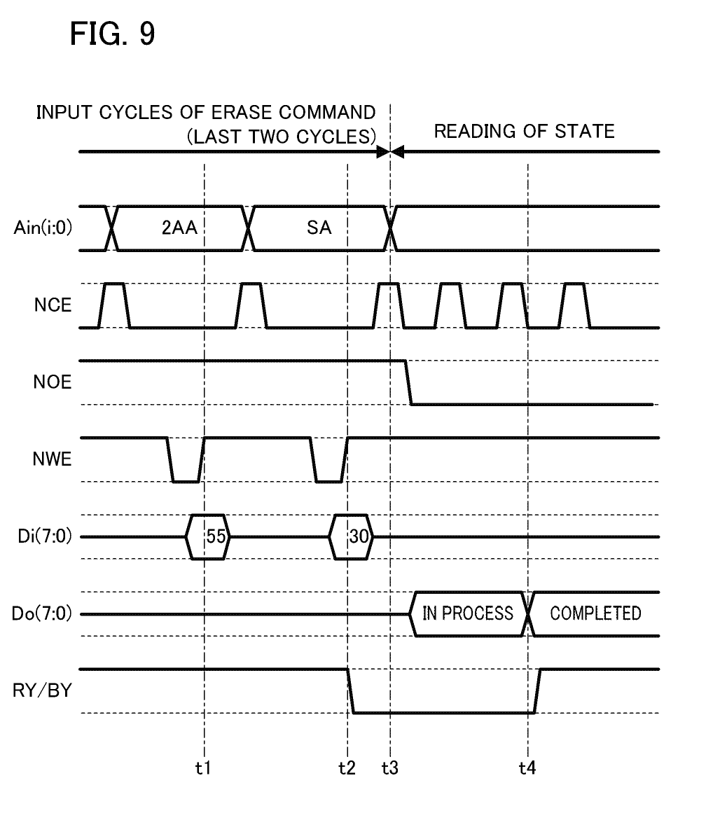

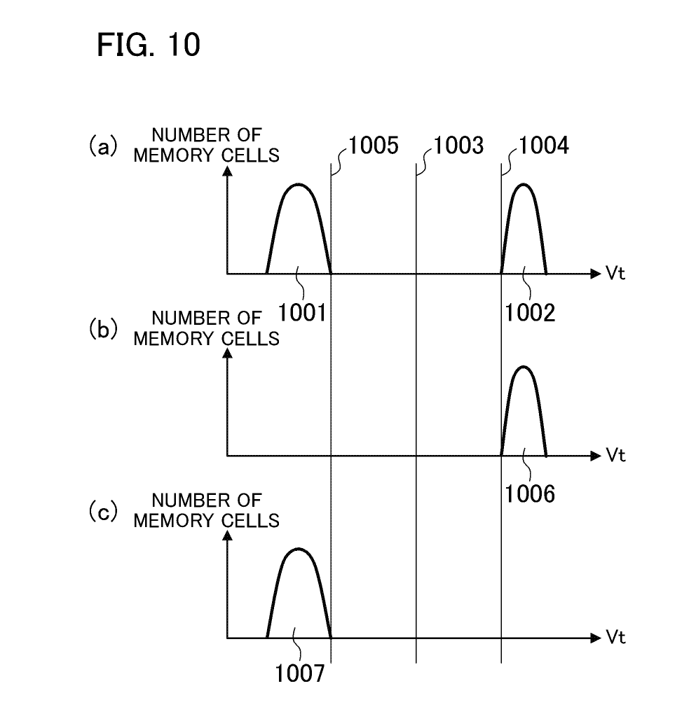

FIGS. 8 and 9 are diagrams showing timings of input and output signals of the flash memory device when an erase command is performed.

FIG. 8 is a timing diagram showing a case where the flash memory device receives an erase command and performs erase operation to set memory cells to the initial state, i.e., the threshold region of the logic 11. Although it typically takes six cycles to input an erase command to the flash memory device, FIG. 8 shows only the last two cycles of the command input.

At timings t1 and t2 at which the control signal NCE is set to “L” and the control signal NWE transitions from “L” to “H,” an address and data shown in FIG. 8 are input to the address input terminal Ain(i:0) and the data input/output terminal DQ(7:0), whereby a sector erase command is input to the flash memory device. An address SA which is input to the address input terminal Ain(i:0) at timing t2 is a sector address at which erase operation is to be performed.

When receiving the address and data input at timing t2, the mode decoder 700 of the control circuit 130 determines that the input command is a sector erase command, and sets the RY/BY signal to “L.” In this case, the control circuit 130 determines, based on the value of the reprogram information CNT, that erase operation with respect to the flash memory device is erase operation in which memory cells are set to the initial state, i.e., the threshold region of the logic 11, and repeatedly performs the erase operation in which memory cells are set to the initial state, until erase verify operation is completed. At timing t4, when erase verify operation is completed, the RY/BY signal control circuit 706 performs a control to set the RY/BY signal to “H.”

Similarly, after t3 at which an erase command input cycle is completed, if read operation is performed with respect to the data storage area 104, the control circuit 130 performs a control to output a signal indicating the operating state of the flash memory device to the data input/output terminal DQ(7:0).

As the signal indicating the operating state, a signal of “L” is read and output as data (data polling signal) to a data output terminal Do(7) if the current time is before t4 (i.e., erase operation is being performed), and a signal of “H” is read and output as data (data polling signal) to the data output terminal Do(7) if the current time is after t4 (i.e., erase operation is completed). Also, data which alternates between “L” and “H” every read operation is output as read data to a data output terminal Do(6) if the current time is before t4 (i.e., erase operation is being performed), and data of “H” is output as read data to the data output terminal Do(6) during every read operation if the current time is after t4 (i.e., erase operation is completed) (toggle bit).

FIG. 9 is a timing diagram showing a case where pseudo-erase operation is performed in which the flash memory device receives an erase command, and reprogram information to the reprogram information storage area 106 and the registers 200-206 of the reprogram information holder circuit 128 is changed without changing the thresholds of memory cells, to change selected reference levels. FIG. 9 is the same as FIG. 8 before timings t1 and t2 at which a sector erase command is input to the flash memory device.

When receiving an address and data input at timing t2, the mode decoder 700 of the control circuit 130 determines that the input command is a sector erase command, and sets the RY/BY signal to “L.” In this case, the control circuit 130 determines, based on the value of the reprogram information CNT, that erase operation with respect to the flash memory device is pseudo-erase operation in which reprogram information to the reprogram information storage area 106 and the registers 200-206 of the reprogram information holder circuit 128 is changed without changing the thresholds of memory cells, to change selected reference levels, and performs data write with respect to the reprogram information storage area 106. At timing t4, when program verify operation is completed, the RY/BY signal control circuit 706 performs a control to set the RY/BY signal to “H.”

Data write to the registers 200-206 of the reprogram information holder circuit 128 can be quickly performed, and therefore, is completed before data write to the reprogram information storage area 106.

The signal indicating the operating state of the flash memory device, which is output to the data input/output terminal DQ(7:0), is controlled in a manner similar to that of FIG. 8.

As shown in FIGS. 8 and 9, in the flash memory device in which, as erase operation, pseudo-erase operation is achieved in which reprogram information to the reprogram information storage area 106 and the registers 200-206 of the reprogram information holder circuit 128 is changed without changing the thresholds of memory cells, to change selected reference levels, the reprogram information CNT is used to control timings at which the RY/BY signal, and the signal indicating the operating state of the flash memory device, which is output to the data input/output terminal DQ(7:0), are controlled, whereby the operating status of the flash memory device can be output to the outside. Therefore, in a system employing the flash memory device of the present disclosure, the control of the flash memory device can be easily achieved.

### Fourth Embodiment

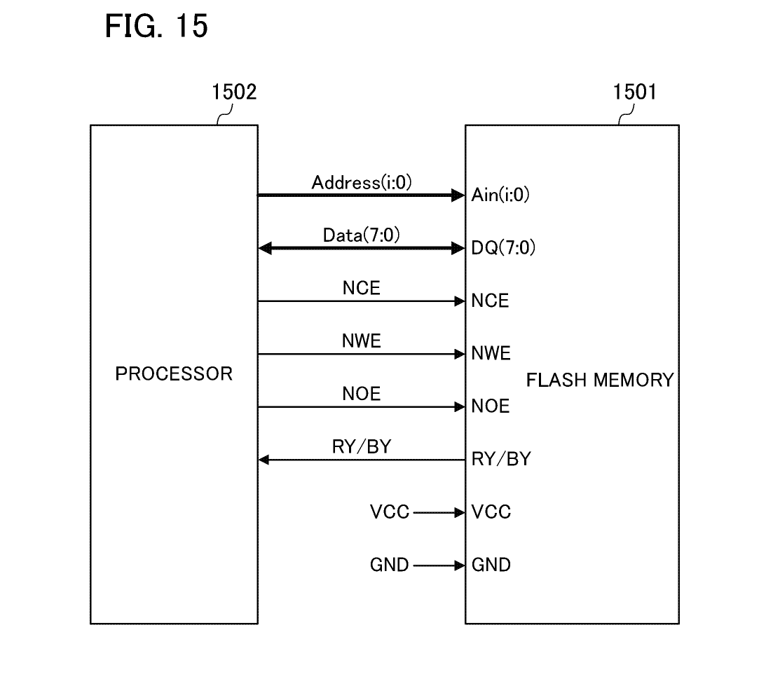

FIG. 15 is a block diagram showing a configuration of a signal processing system according to a fourth embodiment of the present disclosure.

In FIG. 15, a reference character 1501 indicates the flash memory device of the first, second, or third embodiment, and a reference character 1502 indicates a processor connected to the flash memory device 1501. There is the exchange of the following data and information between the flash memory device 1501 and the processor 1502: an address signal Address(i:0); data Data(7:0); control signals NCE, NOE, and NWE; and a state signal RY/BY indicating whether the flash memory device 1501 is operating or is ready to receive an operation command.

The processor 1502 rewrites data of the flash memory device 1501 as follows. The control signals NCE, NOE, and NWE, and the address signal Address(i:0) and the data Data(7:0) as an operation command, are input to the flash memory device 1501. When receiving a program or erase operation command from the processor 1502, the flash memory device 1501 outputs, to the processor 1502, the RY/BY signal indicating whether the flash memory device 1501 is operating or is ready to receive an operation command. The flash memory device 1501 also uses a specific bit of the data Data(7:0) to output a signal indicating whether operation corresponding to the received operation command is being performed or has been completed.

The processor 1502 reads the operating state indicated by the RY/BY signal or the specific bit of the data Data(7:0) from the flash memory device 1501, and determines whether or not the operation of the flash memory device 1501 has been completed.

As described in the first, second, and third embodiments, the erase operation of the flash memory device of the present disclosure includes operation of changing and setting the thresholds of memory cells to the initial state, i.e., the threshold region of the logic 11, and pseudo-erase operation in which reprogram information is written to the reprogram information storage area 106 and the registers 200-206 of the reprogram information holder circuit 128 without changing the thresholds of memory cells. Therefore, when the processor 1502 outputs an erase operation command to the flash memory device 1501, the control timing varies depending on the operation of the flash memory device 1501.

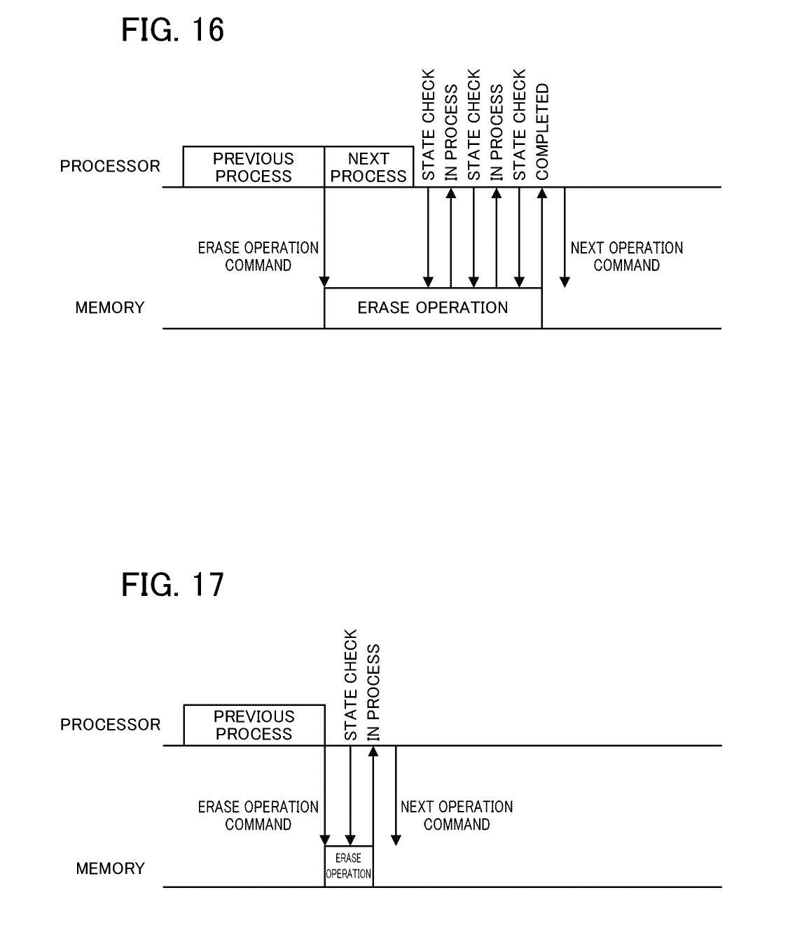

FIG. 16 is a timing diagram showing a case where, in response to an erase operation command from the processor 1502, the flash memory device 1501 performs erase operation in which the thresholds of memory cells are changed.

In FIG. 16, when the processor 1502 outputs an erase command to the flash memory device 1501, the flash memory device 1501 starts erase operation in which the thresholds of memory cells are changed, and outputs the RY/BY signal or the data Data(7:0) indicating that the flash memory device 1501 is operating. In erase operation, it takes a time to change the thresholds of memory cells, and therefore, it takes a time to complete erase operation. While the flash memory device 1501 is performing erase operation, the processor 1502 can perform signal processing, such as a calculation process etc. Thereafter, the processor 1502 receives the RY/BY signal or the data Data(7:0) and regularly checks the operating state of the flash memory device 1501. After completion of erase operation, the flash memory device 1501 outputs the RY/BY signal or the data Data(7:0) indicating that the flash memory device 1501 is ready to receive an operation command or has completed the operation. The processor 1502 receives the signal, and outputs the next operation command to the flash memory device 1501.

Before issuing an erase operation command, the processor 1502 can determine whether the flash memory device 1501 will perform erase operation or pseudo-erase operation in response to the erase operation command from the processor 1502, by reading reprogram information from the flash memory device 1501.

FIG. 17 is a timing diagram showing a case where the flash memory device 1501 performs pseudo-erase operation in response to an erase operation command from the processor 1502.

In FIG. 17, when receiving an erase command output from the processor 1502, the flash memory device 1501 starts erase operation in which the thresholds of memory cells are changed, and outputs the RY/BY signal or the data Data(7:0) indicating that the flash memory device 1501 is operating. In pseudo-erase operation, only program operation is performed, i.e., erase operation is completed without changing the memory cell storage state of the data storage area. Therefore, it is quickly indicated by the RY/BY signal or the data Data(7:0) that the flash memory device 1501 is ready to receive an operation command or has completed the operation. Therefore, the processor 1502 receives the RY/BY signal or the data Data(7:0) to regularly check the operating state of the flash memory device 1501, without performing another process, such as a calculation process etc. After completion of erase operation, the flash memory device 1501 outputs the RY/BY signal or the data Data(7:0) indicating that the flash memory device 1501 is ready to receive an operation command or has completed the operation. In response to this signal, the processor 1502 outputs the next operation command to the flash memory device 1501.

Thus, by reading reprogram information from the flash memory device 1501 prior to the issuance of an erase operation command, the processor 1502 can efficiently control the erase operation of the flash memory device 1501 even if the flash memory device 1501 is one which performs erase operation, or erase operation (pseudo-erase operation) which is performed at a different timing.

### Fifth Embodiment

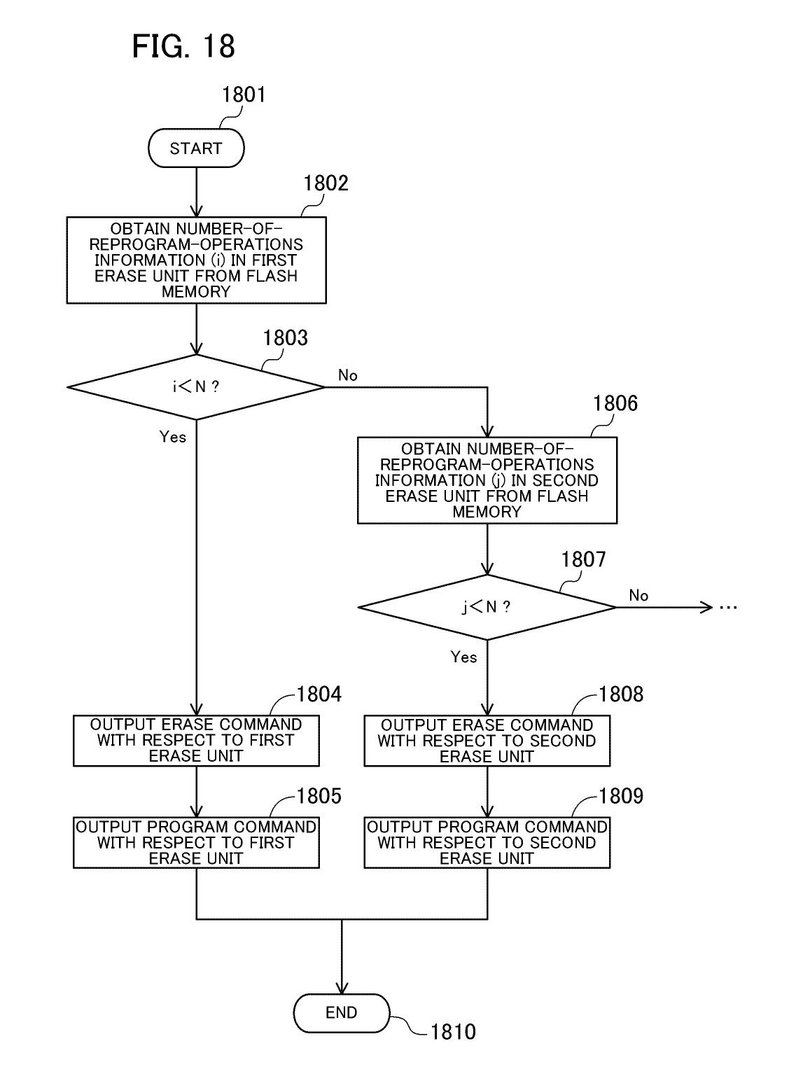

FIG. 18 is a flowchart showing a control method which is used for reprogram operation in a signal processing system according to a fifth embodiment of the present disclosure. Here, the signal processing system of the fifth embodiment is different from the signal processing system of the fourth embodiment in that a memory cell array including a plurality of erase units is provided.

In FIG. 18, a reference character 1801 indicates a start step, a reference character 1802 indicates a step of obtaining the number of reprogram operations (i) as reprogram information of the first erase unit from the flash memory device 1501, a reference character 1803 indicates a step of determining whether or not the number of reprogram operations (i) of the first erase unit obtained from the flash memory device 1501 is less than a setting value N, a reference character 1804 indicates a step of outputting an erase command with respect to the first erase unit, a reference character 1805 indicates a step of outputting a program command with respect to the first erase unit, a reference character 1806 indicates a step of obtaining the number of reprogram operations (j) as reprogram information of the second erase unit from the flash memory device 1501, a reference character 1807 indicates a step of determining whether or not the number of reprogram operations (j) of the second erase unit obtained from the flash memory device 1501 is less than the setting value N, a reference character 1808 indicates a step of outputting an erase command with respect to the second erase unit, a reference character 1809 indicates a step of outputting a program command with respect to the second erase unit, and a reference character 1810 indicates an end step.

In the control method which is performed when the processor 1502 performs reprogram operation with respect to the flash memory device 1501, control proceeds from start step 1801 to step 1802 of obtaining the number-of-reprogram-operations information (i) of the first erase unit from the flash memory device 1501, and then to step 1803 of determining whether or not the number-of-reprogram-operations information (i) obtained in step 1802 is less than the setting value N. The setting value N used in step 1803 is set in association with the number of possible reference levels.

When the determination in step 1803 is positive (i.e., the number-of-reprogram-operations information (i) obtained in step 1802 is less than the setting value N), control proceeds to step 1804 of outputting an erase command with respect to the first erase unit, and then to step 1805 of outputting a program command with respect to the first erase unit. Thereafter, control proceeds to end step 1810. Thus, the reprogram control flow is completed.

When the determination in step 1803 is negative (i.e., the number-of-reprogram-operations information (i) obtained in step 1802 is not less than the setting value N), control proceeds to step 1806 of obtaining the number-of-reprogram-operations information (j) of the second erase unit from the flash memory device 1501. Thereafter, control proceeds to step 1807 of determining whether or not the number-of-reprogram-operations information (j) obtained in step 1806 is less than the setting value N.

When the determination in step 1807 is positive (i.e., the number-of-reprogram-operations information (j) obtained in step 1806 is less than the setting value N), control proceeds to step 1808 of outputting an erase command with respect to the second erase unit, and then to step 1809 of outputting a program command with respect to the second erase unit. Thereafter, control proceeds to end step 1810. Thus, the reprogram control flow is completed.

When the determination in step 1807 is negative (i.e., the number-of-reprogram-operations information (j) obtained in step 1806 is not less than the setting value N), a similar process is repeated with respect to the third erase unit.

As a result, when the erase operation of a non-volatile semiconductor memory device is not completed because of switching of read reference levels, i.e., when the storage states of memory cells need to be changed, high-speed reprogram operation can be invariably achieved by outputting an erase command with respect to different erase units. Erase operation with respect to an erase unit in which the storage states of memory cells need to be changed may be performed in the background when the non-volatile memory device is not operating.

### Sixth Embodiment

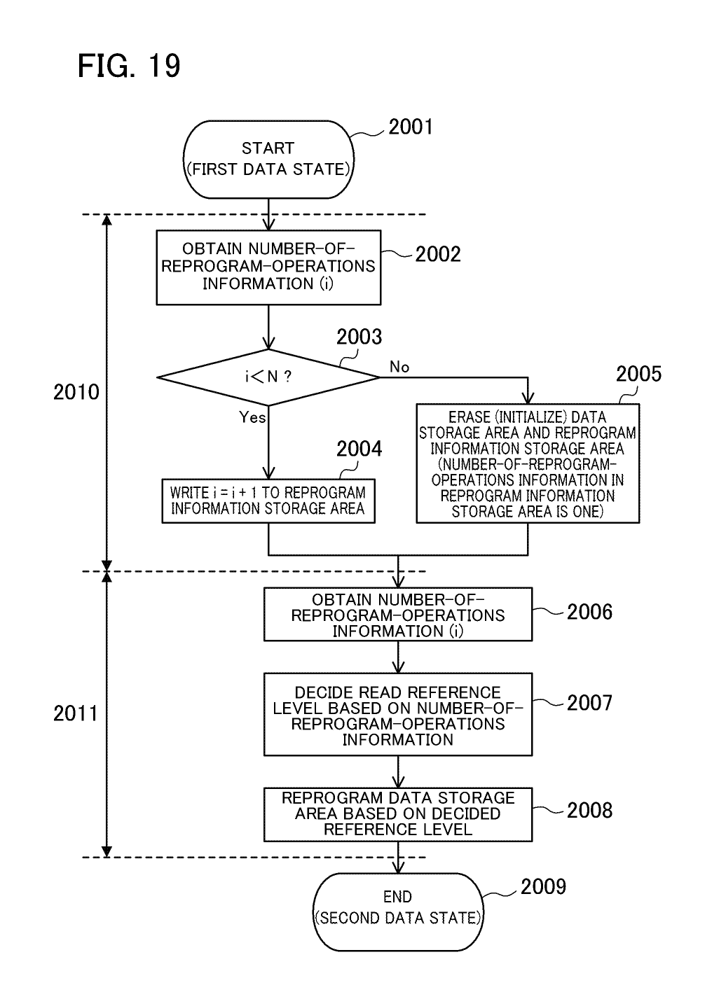

FIG. 19 is a flowchart showing an example method of reprogramming a flash memory device according to a sixth embodiment of the present disclosure. A flow of reprogramming the flash memory device of the first, second, or third embodiment will be described.

In the flowchart of FIG. 19, a reference character 2001 indicates a start step, a reference character 2009 indicates an end step, reference characters 2002, 2004, 2005, 2006, 2007, and 2008 indicates process steps, a reference character 2003 indicates a determination step, and reference characters 2010 and 2011 indicate step ranges.

Steps 2002 and 2006 are each a step of obtaining the number of reprogram operations (i) as reprogram information from the flash memory device. Step 2004 is a step of writing the number of reprogram operations (i) as reprogram information to the reprogram information storage area of the flash memory device. Step 2005 is a step of performing erase operation to initialize the thresholds of the data storage area and the reprogram information storage area. Step 2007 is a step of deciding a read reference level based on the obtained number of reprogram operations (i). Step 2008 is a step of writing new data to the data storage area based on the decided reference level. Step 2003 is a step of determining whether or not the obtained number of reprogram operations (i) is less than a setting value N. The reference character 2010 indicates the range of steps of erase operation with respect to the data storage area, and the reference character 2011 indicates the range of steps of program operation with respect to the data storage area.

The flow of reprogramming a predetermined non-volatile memory cell array begins at start step 2001. Thereafter, control proceeds to step 2002 of obtaining the number of reprogram operations (i), and then to step 2003 of determining whether or not the number of reprogram operations (i) obtained in step 2002 is less than the setting value N.

The setting value N used in step 2003 is set in association with the number of possible reference levels.

When the determination in step 2003 is positive (i.e., the number of reprogram operations (i) obtained in step 2002 is less than the setting value N), control proceeds to step 2004 of writing information indicating the number of reprogram operations (i) to the reprogram information storage area. The number-of-reprogram-operations information which is to be written in step 2004 indicates a value which is obtained by adding one to the number-of-reprogram operations obtained in step 2002. Specifically, when the number of reprogram operations obtained in step 2002 is (i), the number-of-reprogram-operations information which is to be written in step 2004 indicates (i+1).

When the determination in step 2003 is negative (i.e., the number of reprogram operations (i) obtained in step 2002 is not less than the setting value N), control proceeds to step 2005 of performing erase operation to initialize the data storage area and the reprogram information storage area.

Step 2005 is a step of performing erase operation with respect to the flash memory device to initialize the thresholds of memory cells. Step 2005 includes applying an erase pulse, performing erase verify operation, performing preprogram operation to cause all the memory cells to be in the same state (e.g., “0”) before erase operation, etc.

In this embodiment, the reprogram information storage area is also erased in step 2005. Therefore, the reprogram information storage area is initialized at the end of step 2005, e.g., the number-of-reprogram-operations information (i.e., the number of reprogram operations (i)) is set to one.

The range 2010 from step 2002 to step 2004 or 2005 is the step range of erase operation in program operation according to the present disclosure.

After each of steps 2004 and 2005, control proceeds to step 2006 of obtaining the number of reprogram operations (i) as reprogram information from the flash memory device. In step 2006, the number of reprogram operations (i) changed by step 2004 or 2005 is obtained. Specifically, in the above example, (i)=(i+1) in step 2004 or (i=1) in step 2005.

After step 2006, control proceeds to step 2007 of deciding a read reference level based on the number of reprogram operations (i) obtained from the flash memory device. In step 2007, a reference level corresponding to the number-of-reprogram-operations information is selected from a plurality of read reference levels.

After step 2007, control proceeds to step 2008 of writing new data to the data storage area based on the decided reference level.

Step 2008 also includes applying a program pulse, performing program verify operation, etc.

Thereafter, control proceeds to end step 2009. Thus, the flow of the reprogram method is completed.

In the present disclosure, by storing reprogram information in the reprogram information storage area of the flash memory device cell array during erase operation, data can be read and newly rewritten while achieving the object of the present disclosure even if the power supply is interrupted.

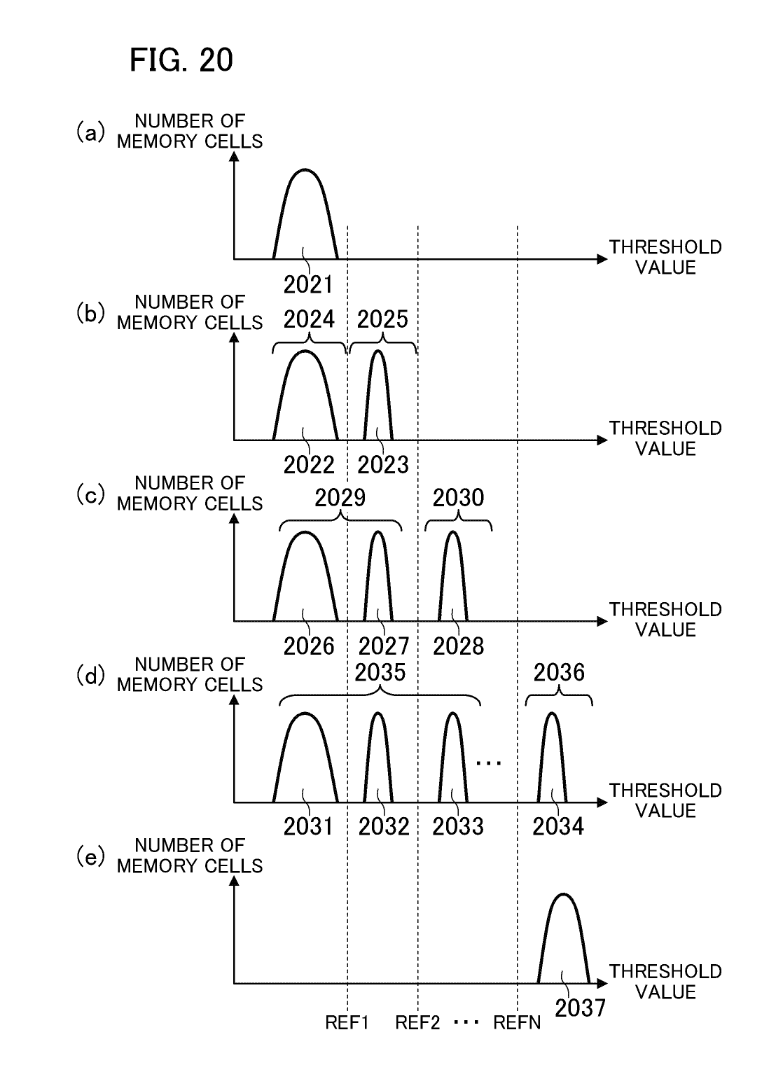

Next, the transition of the memory array in a reprogram flow of the flash memory device of the sixth embodiment of the present disclosure will be described with reference to FIG. 20.

FIG. 20 is a diagram showing distributions of memory cell threshold voltages Vt of the flash memory device, where the horizontal axis indicates memory cell threshold voltages Vt and the vertical axis indicates numbers of memory cells. In FIG. 20, reference characters 2021, 2022, 2023, 2026, 2027, 2028, 2031, 2032, 2033, 2034, and 2037 indicate setting regions for memory cell threshold voltages Vt, reference characters 2024, 2029, and 2035 indicate the first logic value, reference characters 2025, 2030, and 2036 indicate the second logic value, and reference characters REF1, REF2, . . . , and REFN indicate read reference levels.

A portion (a) of FIG. 20 shows the initial state (the first data state), in which (i=1) is stored in the reprogram information storage area, REF1 is selected as a read reference level, and, for example, all data are determined to have “1.”

This state is obtained at the end of step 2005 of FIG. 19. Next, therefore, data write will be described.

When the number of reprogram operations (i) is obtained as reprogram information from the flash memory device, (i=1) is obtained, and REF1 is decided as a read reference level based on the number-of-reprogram-operations information. When data is written to the data storage area based on the decided reference level REF1, the flash memory device transitions to a state shown in a portion (b) of FIG. 20, i.e., the second data state. The first and second logic values 2024 and 2025 are determined to have “1” and “0,” respectively.

In the state of the portion (b) of FIG. 20, reprogram operation is similarly performed. The number of reprogram operations (i=1) is obtained as reprogram information. Because (i=1) is less than N, (i=2) is written to the reprogram information storage area. Thus, the erase operation of the present disclosure is completed. Next, when the number of reprogram operations (i) is obtained as reprogram information, (i=2) is obtained. REF2 is decided as a read reference level based on the number-of-reprogram operations information. When data is written to the data storage area based on the decided reference level REF2, the flash memory device transitions to a state shown in a portion (c) of FIG. 20, i.e., the second data state. The first and second logic values 2029 and 2030 are determined to have “1” and “0,”, respectively.

When there are N selectable reference levels, a reference level REFN is selected in a state shown in a portion (d) of FIG. 20, and the first and second logic values 2035 and 2036 are determined to have “1” and “0,” respectively (highest data state).

In the state of the portion (d) of FIG. 20, reprogram operation is performed as follows. The number of reprogram operations (i) is obtained as reprogram information, i.e., (i=N) is obtained. Because (i=N) is not less than N, the data storage area and the reprogram information storage area are erased. In this case, before erase operation, the flash memory device transitions to a state shown in a portion (e) of FIG. 20 in which all the memory cells are caused to have “0,” and then to the state of the portion (a) of FIG. 20. The number of reprogram operations (i) in the reprogram information storage area is set to (i=1). Thus, the erase operation of the present disclosure is completed. Subsequent program operation is performed as described above.

Thus, selectable read reference levels, the number of which is equal to the predetermined value N of step 2003, are provided, and a read reference level is selected based on the number of reprogram operations (i). As a result, the number of erase operations in which the thresholds of memory cells are initialized can be reduced in reprogram operation, whereby the reliability can be improved and the reprogram speed can be increased.

In the reprogram operation flow of FIG. 19, the reprogram speed can be increased. However, in reprogram operation after reprogram operation is performed a predetermined number of times, erase operation in which the thresholds of memory cells are initialized is performed, and therefore, the number of reprogram operations which can be performed at high speed cannot be arbitrarily set, which is inconvenient.

### Seventh Embodiment

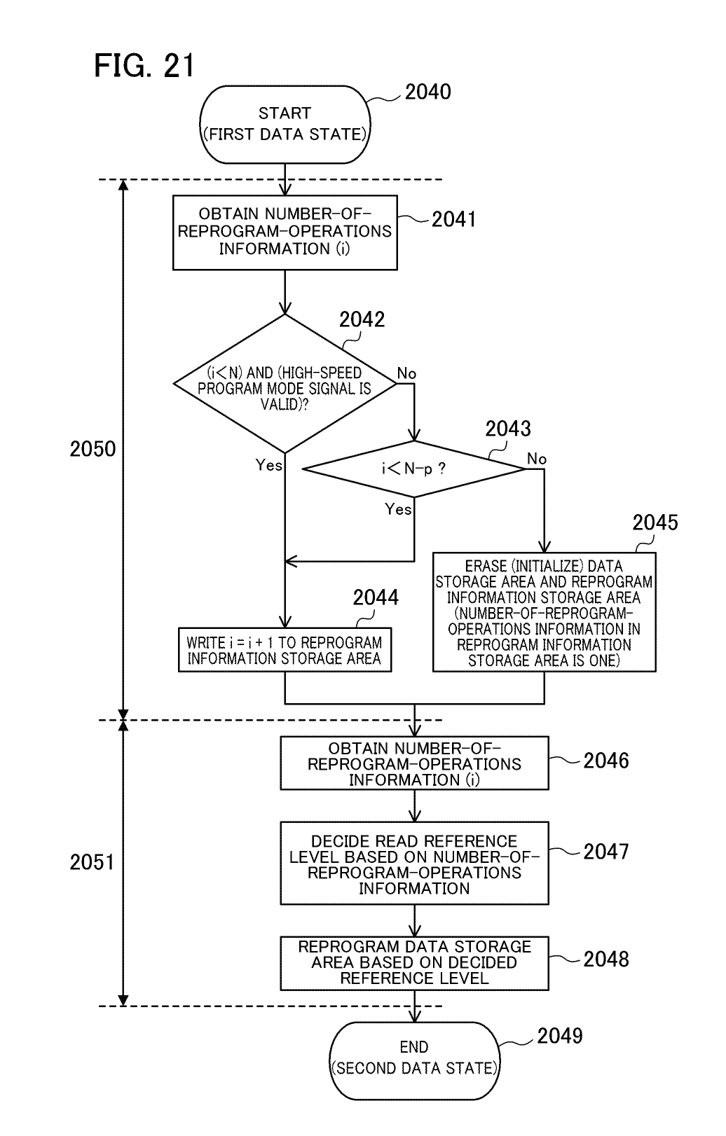

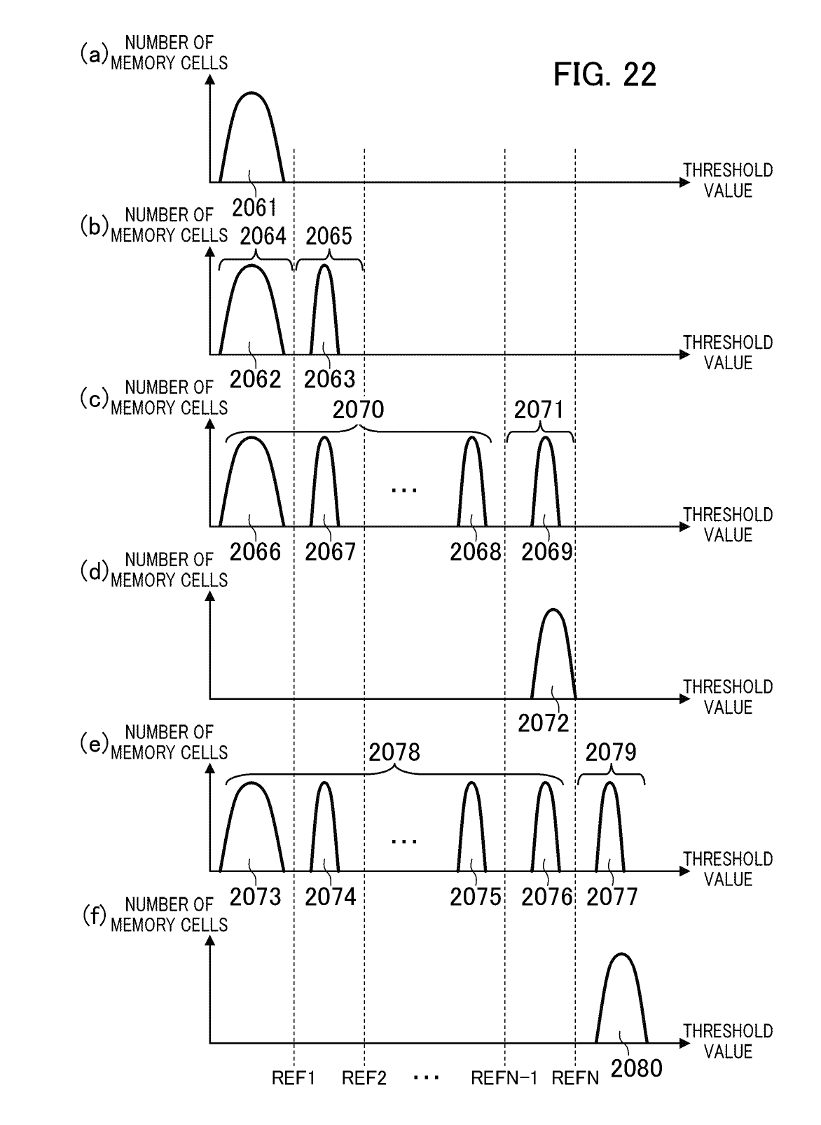

FIG. 21 is a flowchart showing an example method of reprogramming a flash memory device according to a seventh embodiment of the present disclosure.

In the flowchart of FIG. 21, a reference character 2040 indicates a start step, a reference character 2049 indicates an end step, reference characters 2041, 2044, 2045, 2046, 2047, and 2048 indicate process steps, reference characters 2042 and 2043 indicates determination steps, and reference characters 2050 and 2051 indicate step ranges.

Steps 2041 and 2046 are each a step of obtaining the number of reprogram operations (i) as reprogram information from the flash memory device. Step 2044 is a step of writing the number of reprogram operations (i) as reprogram information to the reprogram information storage area of the flash memory device. Step 2045 is a step of performing erase operation to initialize the thresholds of the data storage area and the reprogram information storage area. Step 2047 is a step of deciding a read reference level from the obtained number of reprogram operations (i). Step 2048 is a step of writing new data to the data storage area based on the decided reference level. Step 2042 is a step of determining whether or not the number of reprogram operations (i) obtained as reprogram information is less than a first setting value N and a high-speed program mode signal is valid. Step 2043 is a step of determining whether or not the number of reprogram operations (i) obtained as reprogram information is less than a second setting value (N−p). The reference character 2050 indicates the range of steps of data erase operation of the data storage area, and the reference character 2051 indicates the range of steps of data write (program) operation of the data storage area.

The flow of reprogramming a predetermined non-volatile memory cell array begins at start step 2040. Thereafter, control proceeds to step 2041 of obtaining the number of reprogram operations (i) as reprogram information, and then to step 2042 of determining whether or not the number of reprogram operations (i) obtained in step 2041 is less than the first setting value N and the high-speed program mode signal is valid.

As used herein, the high-speed program mode signal refers to a signal which is valid “H” when reprogram operation requires high-speed write, and is invalid “L” when reprogram operation can be accompanied by erase operation in which the thresholds of memory cells are initialized.

The first setting value N used in step 2042 is set in association with the number of possible reference levels.

When the determination in step 2042 is positive (i.e., the obtained number of reprogram operations (i) is less than the first setting value N and the high-speed program mode signal is valid), control proceeds to step 2044 of writing the number of reprogram operations (i) as number-of-reprogram-operations information to the reprogram information storage area. The number-of-reprogram-operations information which is to be written in this case indicates a value which is obtained by adding one to the number-of-reprogram operations obtained in step 2041. Specifically, when the number of reprogram operations obtained in step 2041 is (i), the number-of-reprogram-operations information which is to be written in step 2042 indicates (i+1).

When the determination in step 2042 is negative (i.e., the number of reprogram operations (i) is not less than the setting value N or the high-speed program mode signal is invalid), control proceeds to step 2043 of determining whether or not the number-of-reprogram operations information obtained in step 2041 is less than the second setting value (N−p).

The second setting value (N−p) used in step 2043 is set in association with the number of possible reference levels and the first setting value N.

When the determination in step 2043 is positive (i.e., the number of reprogram operations (i) obtained as reprogram information is less than the second setting value (N−p)), control proceeds to step 2044 of writing the number-of-reprogram-operations information to the reprogram information storage area.

When the determination in step 2043 is negative (i.e., the number of reprogram operations (i) obtained as reprogram information is not less than the second setting value (N−p)), control proceeds to step 2045 of performing erase operation to initialize the data storage area and the reprogram information storage area.

Step 2045 is a step of performing erase operation with respect to the flash memory device. Step 2045 includes applying an erase pulse, performing erase verify operation, performing preprogram operation to cause all the memory cells to be in the same state (e.g., “0”) before erase operation, etc.

In this embodiment, the reprogram information storage area is also erased by step 2045. Therefore, at the end of step 2045, the reprogram information storage area is initialized, and for example, the number-of-reprogram operations information is set as the number of reprogram operations (i) to one.

The range 2050 from step 2041 to step 2044 or 2045 is the step range of erase operation in program operation according to the present disclosure.

After each of steps 2044 and 2045, control proceeds to step 2046 of obtaining the number of reprogram operations (i) as reprogram information. In step 2046, the number of reprogram operations (i) changed by step 2044 or 2045 is obtained. Specifically, in the above example, (i)=(i+1) in step 2044 or (i=1) in step 2045.

After step 2046, control proceeds to step 2047 of deciding a read reference level based on the number-of-reprogram-operations information obtained as reprogram information. In step 2047, a reference level corresponding to the number-of-reprogram-operations information is selected from a plurality of read reference levels.

After step 2047, control proceeds to step 2048 of writing new data to the data storage area based on the decided reference level.

Step 2048 also includes applying a program pulse, performing program verify operation, etc.

Thereafter, control proceeds to end step 2049. Thus, the reprogram method flow is completed.

Thus, selectable read reference levels, the number of which is equal to the predetermined value N of step 2042, are provided, and a read reference level is selected based on the number of reprogram operations (i). As a result, the number of erase operations in which the thresholds of memory cells are initialized can be reduced in reprogram operation, whereby the reliability can be improved and the reprogram speed can be increased.

When the high-speed program mode signal is set to be valid in reprogram operation, the erase operation of step 2045 in which the thresholds of memory cells are initialized is not performed, and by setting the first predetermined value and the second predetermined value to N and (N−p), respectively, high-speed reprogram operation can be achieved when desired, although the number of reprogram operations defined in the specifications is p.

Next, the transition of the memory array in the flow of reprogram operation with respect to the flash memory device of the seventh embodiment of the present disclosure will be described with reference to FIG. 22.

FIG. 22 is a diagram showing distributions of memory cell threshold voltages Vt of the flash memory device, where the horizontal axis indicates memory cell threshold voltages Vt and the vertical axis indicates numbers of memory cells. In FIG. 22, reference characters 2061, 2062, 2063, 2066, 2067, 2068, 2069, 2072, 2073, 2074, 2075, 2076, 2077, and 2080 indicate setting regions for memory cell threshold voltages Vt, reference characters 2064, 2070, and 2078 indicate the first logic value, reference characters 2065, 2071, and 2079 indicate the second logic value, and REF1, REF2, . . . , REFN-1, and REFN indicate read reference levels.

A portion (a) of FIG. 22 shows the initial state (the first data state), in which (i=1) is stored in the reprogram information storage area, REF1 is selected as a read reference level, and, for example, all data are determined to have “1.”

This state is obtained at the end of step 2045 of FIG. 22. Next, therefore, data write following step 2045 will be described.

When the number of reprogram operations (i) is obtained as reprogram information, (i=1) is obtained, and REF1 is decided as a read reference level based on the number-of-reprogram-operations information. When data is written to the data storage area based on the decided reference level REF1, the flash memory device transitions to a state shown in a portion (b) of FIG. 22, i.e., the second data state. The first and second logic values 2064 and 2065 are determined to have “1” and “0,” respectively.

Assuming that the first predetermined value is N and the second predetermined value is N−1, when the high-speed program mode signal is invalid, a reference level R(N−1) is selected in a state shown in a portion (c) of FIG. 22, and the first and second logic values 2070 and 2071 are determined to have “1” and “0,” respectively (highest data state).

In the state of the portion (c) of FIG. 22, when the high-speed program mode signal is invalid, reprogram operation is performed as follows. When the number of reprogram operations (i) is obtained as reprogram information, (i)=N−1 is obtained. Because the high-speed program mode signal terminal is invalid and (i) is not less than N, the data storage area and the reprogram information storage area are erased. In this case, preprogram operation in which all the memory cells are set to “0” is performed before erase operation, and thereafter, the flash memory device transitions to a state shown in a portion (d) of FIG. 22, and then to the state of the portion (a) of FIG. 22. A value (i=1) is written to the reprogram information storage area. Thus, the erase operation of the present disclosure is completed.

Subsequent program operation is performed as described above.

In the state of the portion (c) of FIG. 22, when the high-speed program mode signal is valid, reprogram operation is performed as follows. When the number of reprogram operations (i) is obtained as reprogram information, (i)=N−1 is obtained. Because the high-speed program mode signal is valid and (i) is less than N, (i)=N is written to the reprogram information storage area. Thus, the erase operation of the present disclosure is completed. Next, when the number of reprogram operations (i) is obtained as reprogram information, (i)=N is obtained, and REFN is decided as a read reference level based on the number-of-reprogram operations information. When data is written to the data storage area based on the decided reference level REFN, the flash memory device transitions to a state shown in a portion (e) of FIG. 22, i.e., the second data state. The first and second logic values 2078 and 2079 are determined to have “1” and “0,” respectively.

In the state of the portion (e) of FIG. 22, reprogram operation is performed as follows. When the number of reprogram operations (i) is obtained as reprogram information, (i) =N is obtained. Because (i) is not less than N and is not less than N−1, the data storage area and the reprogram information storage area are erased. In this case, preprogram operation in which all the memory cells are set to “0” is performed before erase operation, and the flash memory device transitions to a state shown in a portion (f) of FIG. 22, and then to the state of the portion (a) of FIG. 22. The reprogram information storage area is set to (i=1). Thus, the erase operation of the present disclosure is completed. Subsequent program operation is performed as described above.

Thus, by performing erase operation in which the thresholds of memory cells are initialized in reprogram operation when the number of selectable reference levels is less than the maximum value, a spare selectable read reference level can be ensured. Therefore, during desired reprogram operation, data rewrite can be performed at high speed without performing erase operation in which the thresholds of memory cells are changed.

In the above embodiments of the present disclosure, a flash memory device in which the thresholds of memory cells are stored information has been described as an example non-volatile memory device. Of course, when the present disclosure is applied to MRAM and ReRAM, in which the resistance values of memory cells are stored information, and other non-volatile memory devices, similar advantages can be obtained.

Although a reference level for read operation has been described above as an example, similar advantages can, of course, be obtained even when a reference current value for read operation is used. Moreover, although it has been assumed above that the programmed state has the logic 0 and the erased state has the logic 1, similar advantages can, of course, be obtained in the opposite case where the programmed state has the logic 1 and the erased state has the logic 0.

As described above, the present disclosure can provide high-speed read operation and high-speed reprogram operation while reducing or preventing the degradation of the data hold capability, and is useful for non-volatile memory, such as flash memory etc.

1. A non-volatile semiconductor memory device comprising:
a memory cell array including a data storage area including a plurality of memory cells having a plurality of possible storage states and a reprogram information storage area configured to store reprogram information;
a read circuit configured to determine a memory cell storage state of the memory cell array;
a reprogram information holder configured to store data read from the reprogram information storage area;
a first read reference signal configured to determine a memory cell storage state of the data storage area in which a first storage state is stored as a first logic value and a second storage state is stored as a second logic value;
a second read reference signal configured to determine a memory cell storage state of the data storage area in which the first and second storage states are stored as a first logic value and a third storage state is stored as a second logic value; and
a read reference signal selector configured to select and output one of the first and second read reference signals to the read circuit, based on an output of the reprogram information holder.

2. A non-volatile semiconductor memory device comprising:
a memory cell array including a data storage area including a plurality of memory cells having a plurality of possible storage states and a reprogram information storage area configured to store reprogram information;
a first read circuit configured to determine a memory cell storage state of the data storage area;
a first read reference signal configured to determine a memory cell storage state of the data storage area in which a first storage state is stored as a first logic value and a second storage state is stored as a second logic value;
a second read reference signal configured to determine a memory cell storage state of the data storage area in which the first and second storage states are stored as a first logic value and a third storage state is stored as a second logic value;
a second read circuit configured to determine a state of the reprogram information storage area; and
a read reference signal selector configured to select and output one of the first and second read reference signals to the first read circuit, based on an output of the second read circuit.

3. A non-volatile semiconductor memory device comprising:
a memory cell array including a data storage area including a plurality of memory cells having a plurality of possible storage states and a reprogram information storage area configured to store reprogram information;
a first and a second read circuit configured to determine a memory cell storage state of the data storage area;
a reprogram information holder configured to store data read from the reprogram information storage area;
a first read reference signal configured to be input to the first read circuit to determine a memory cell storage state of the data storage area in which a first storage state is stored as a first logic value and a second storage state is stored as a second logic value; and
a second read reference signal configured to be input to the second read circuit to determine a memory cell storage state of the data storage area in which the first and second storage states are stored as a first logic value and a third storage state is stored as a second logic value,
wherein
one of outputs of the first and second read circuits is selected to output data read from at least one of the plurality of memory cells of the data storage area, based on an output of the reprogram information holder.

4. The non-volatile semiconductor memory device of claim 1, wherein
the first state is an erase level state and the second state is a first program level state, and
the third state is a second program level state which is different from the first program level state.

5. The non-volatile semiconductor memory device of claim 1, wherein
the first logic value has a logic 1 and the second logic value has a logic 0.

6. The non-volatile semiconductor memory device of claim 1, wherein
the first logic value has a logic 0 and the second logic value has a logic 1.

7. The non-volatile semiconductor memory device of claim 1, wherein
the reprogram information holder includes a register configured to store data read from the reprogram information storage area.

8. The non-volatile semiconductor memory device of claim 1, wherein
the read reference signal selector includes a switch configured to be controlled based on an output of the reprogram information holder.

9. The non-volatile semiconductor memory device of claim 2, wherein
the read reference signal selector includes a switch configured to be controlled based on the output of the second read circuit.

10. The non-volatile semiconductor memory device of claim 3, further comprising:
a selector configured to select one of the outputs of the first and second read circuits based on the output of the reprogram information holder.

11. A non-volatile semiconductor memory device comprising:
a memory cell array including a data storage area including a plurality of memory cells having a plurality of possible storage states and a reprogram information storage area configured to store reprogram information;
a read circuit configured to determine a memory cell storage state of the memory cell array;
a signal terminal configured to receive an address signal configured to identify at least one of the plurality of memory cells of the data storage area and a control signal configured to control operation timing;
a signal terminal configured to receive and output data, and receive a control command signal configured to set an operating mode;
a control circuit configured to receive the control command signal and control internal operation;
a signal terminal configured to output a state signal indicating whether the internal operation is being performed or is in a control command receive ready state,
a plurality of read reference signals configured to read a memory cell storage state of the data storage area; and
a read reference signal selector configured to selectively output the plurality of read reference signals to the read circuit,
wherein
the non-volatile semiconductor memory device, when receiving an erase command as the control command signal, selectively switches the plurality of read reference signals, and outputs the state signal indicating the control command receive ready state.

12. A non-volatile semiconductor memory device comprising:
a memory cell array including a data storage area including a plurality of memory cells having a plurality of possible storage states and a reprogram information storage area configured to store reprogram information;
a plurality of read reference signals configured to read a memory cell storage state of the data storage area;
a plurality of read circuits configured to receive the plurality of read reference signals to determine the memory cell storage state of the data storage area;
a signal terminal configured to receive an address signal configured to identify at least one of the plurality of memory cells of the data storage area and a control signal configured to control operation timing;
a signal terminal configured to receive and output data, and receive a control command signal configured to set an operating mode;
a control circuit configured to receive the control command signal and control internal operation; and
a signal terminal configured to output a state signal indicating whether the internal operation is being performed or is in a control command receive ready state, wherein
the non-volatile semiconductor memory device, when receiving an erase command as the control command signal, selectively switches the plurality of read circuits, and outputs the state signal indicating the control command receive ready state.

13. A signal processing system comprising:
a non-volatile semiconductor memory device; and
a processor,
wherein
the non-volatile semiconductor memory device includes
a memory cell array including a data storage area including a plurality of memory cells having a plurality of possible storage states and a reprogram information storage area configured to store reprogram information,
a read circuit configured to determine a memory cell storage state of the memory cell array,
a signal terminal configured to receive an address signal configured to identify at least one of the plurality of memory cells of the data storage area and a control signal configured to control operation timing,
a signal terminal configured to receive and output data, and receive a control command signal configured to set an operating mode,
a control circuit configured to receive the control command signal and control internal operation,
a signal terminal configured to output a state signal indicating whether the internal operation is being performed or is in a control command receive ready state,
a plurality of read reference signals configured to read a memory cell storage state of the data storage area, and
a read reference signal selector configured to selectively output the plurality of read reference signals to the read circuit,
the non-volatile semiconductor memory device, when receiving an erase command as the control command signal, selectively switches the plurality of read reference signals, and outputs the state signal indicating the control command receive ready state, and
the processor includes
a signal terminal configured to output the address signal and the control signal to the non-volatile semiconductor memory device,
a signal terminal configured to receive and output data, and output the control command signal, and
a signal terminal configured to receive the state signal, and
the processor outputs the erase command to the non-volatile semiconductor memory device, reads the state signal of the non-volatile semiconductor memory device, and determines whether or not erase operation with respect to the non-volatile semiconductor memory device has been completed.

14. A signal processing system comprising:
a non-volatile semiconductor memory device; and
a processor,
wherein
the non-volatile semiconductor memory device includes
a memory cell array including a data storage area including a plurality of memory cells having a plurality of possible storage states and a reprogram information storage area configured to store reprogram information,
a plurality of read reference signals configured to read a memory cell storage state of the data storage area,
a plurality of read circuits configured to receive the plurality of read reference signals to determine the memory cell storage state of the data storage area,
a signal terminal configured to receive an address signal configured to identify at least one of the plurality of memory cells of the data storage area and a control signal configured to control operation timing,
a signal terminal configured to receive and output data, and receive a control command signal configured to set an operating mode,
a control circuit configured to receive the control command signal and control internal operation, and
a signal terminal configured to output a state signal indicating whether the internal operation is being performed or is in a control command receive ready state, and
the non-volatile semiconductor memory device, when receiving an erase command as the control command signal, selectively switches the plurality of read circuits, and outputs the state signal indicating the control command receive ready state, and
the processor includes
a signal terminal configured to output the address signal and the control signal to the non-volatile semiconductor memory device,
a signal terminal configured to receive and output data, and output the control command signal, and
a signal terminal configured to receive the state signal, and
the processor outputs the erase command to the non-volatile semiconductor memory device, reads the state signal of the non-volatile semiconductor memory device, and determines whether or not erase operation with respect to the non-volatile semiconductor memory device has been completed.

15. The non-volatile semiconductor memory device of claim 1, wherein
the plurality of storage states of each memory cell are a plurality of threshold values.

16. The non-volatile semiconductor memory device of claim 1, wherein
the plurality of storage states of each memory cell are a plurality of resistance values.

17. The non-volatile semiconductor memory device of claim 1, wherein
the read reference signal indicates a read reference current value.

18. The signal processing system of claim 13, wherein
the state signal is a ready/busy signal which indicates whether the non-volatile semiconductor memory device is operating or is ready to receive a control command, and is output to a specific signal terminal.

19. The signal processing system of claim 13, wherein
the state signal is a data polling signal which is output, to a data terminal, as a signal indicating whether the non-volatile semiconductor memory device is operating or has completed operation.

20. A method for controlling a signal processing system comprising a non-volatile semiconductor memory device and a processor, wherein
the non-volatile semiconductor memory device includes
a memory cell array including a data storage area including a plurality of memory cells having a plurality of possible storage states and a reprogram information storage area configured to store reprogram information, where the memory cell array is divided into a plurality of erase units,
a read circuit configured to determine a state of at least one of the plurality of memory cells,
a signal terminal configured to receive an address signal configured to identify at least one of the plurality of memory cells, and a control signal configured to control operation timing,
a signal terminal configured to receive and output data, and receive a control command signal configured to set an operating mode,
a control circuit configured to receive the control command signal and control internal operation,
a signal terminal configured to output a state signal indicating whether the internal operation is being performed or is in a control command receive ready state,
a plurality of read reference signals configured to read data stored in at least one of the plurality of memory cells, and
a read reference signal selector configured to selectively output the plurality of read reference signals to the read circuit, and
the processor includes
a signal terminal configured to output the address signal and the control signal to the non-volatile semiconductor memory device,
a signal terminal configured to receive and output data, and output the control command signal, and
a signal terminal configured to receive the state signal, and
the non-volatile semiconductor memory device, when receiving an erase command as the control command signal, selectively switches the plurality of read reference signals, and outputs the state signal indicating the control command receive ready state, and
the processor reads reprogram information of a first erase unit from the non-volatile semiconductor memory device, and if it is necessary to change a storage state of at least one of the plurality of memory cells in the first erase unit when outputting an erase command, outputs the erase command with respect to a second erase unit which is different from the first erase unit.

21. A method for controlling a signal processing system comprising a non-volatile semiconductor memory device and a processor, wherein
the non-volatile semiconductor memory device includes
a memory cell array including a data storage area including a plurality of memory cells having a plurality of possible storage states and a reprogram information storage area configured to store reprogram information, where the memory cell array is divided into a plurality of erase units,
a plurality of read reference signals configured to read data stored in at least one of the plurality of memory cells,
a plurality of read circuits configured to receive the plurality of read reference signals to determine a state of at least one of the plurality of memory cells,
a signal terminal configured to receive an address signal configured to identify at least one of the plurality of memory cells, and a control signal configured to control operation timing,
a signal terminal configured to receive and output data, and receive a control command signal configured to set an operating mode,
a control circuit configured to receive the control command signal and control internal operation,
a signal terminal configured to output a state signal indicating whether the internal operation is being performed or is in a control command receive ready state, and
a read reference signal selector configured to selectively output the plurality of read reference signals to the plurality of read circuits, and
the processor includes
a signal terminal configured to output the address signal and the control signal to the non-volatile semiconductor memory device,
a signal terminal configured to receive and output data, and output the control command signal, and
a signal terminal configured to receive the state signal, and
the non-volatile semiconductor memory device, when receiving an erase command as the control command signal, selectively switches the plurality of read circuits, and outputs the state signal indicating the control command receive ready state, and
the processor reads reprogram information of a first erase unit from the non-volatile semiconductor memory device, and if it is necessary to change a storage state of at least one of the plurality of memory cells in the first erase unit when outputting an erase command, outputs the erase command with respect to a second erase unit which is different from the first erase unit.

22. The method of claim 20, wherein
the processor, after outputting a program command with respect to the second erase unit, reads the state signal of the non-volatile semiconductor memory device, and if the state signal indicates the control command receive ready state, erases the first erase unit into an initial state.

23. The method of claim 20, wherein
the plurality of erase units are N different erase units, where N is two or more, and
the processor outputs a program command with respect to one of the N erase units.

24. A method for reprogramming a non-volatile semiconductor memory device, wherein
the non-volatile semiconductor memory device includes
a memory cell array including a data storage area including a plurality of memory cells having a plurality of possible storage states and a reprogram information storage area configured to store reprogram information,
a read circuit configured to determine a memory cell storage state of the data storage area, and
a plurality of read reference signals, and
read operation is performed using the plurality of read reference signals,
when reprogram operation is performed in a first data state in which a first logic value or a second logic value is written in the data storage area,
then if information in the reprogram information storage area indicates that the number of reprogram operations is less than a predetermined value, reprogram information obtained by adding one to the number of reprogram operations is written to the reprogram information storage area, and based on the information indicating the number of reprogram operations stored in the reprogram information storage area, the plurality of read reference signals are selected, and data is written to a second data state different from the first data state, or
then if the information in the reprogram information storage area indicates the predetermined value, the data storage area and the reprogram information storage area are erased, and based on the information indicating the number of reprogram operations stored in the reprogram information storage area, one is selected from the plurality of read reference signals, and with reference to the selected read reference signal, data is written into a second data state which is different from the first data state, and
the predetermined value is set in association with the number of the plurality of possible read reference signals.

25. A method for reprogramming a non-volatile semiconductor memory device, wherein
the non-volatile semiconductor memory device includes
a memory cell array including a data storage area including a plurality of memory cells having a plurality of possible storage states and a reprogram information storage area configured to store reprogram information,
a high-speed program mode signal terminal,
a read circuit configured to determine a memory cell storage state of the data storage area, and
a plurality of read reference signals, and
read operation is performed using the plurality of read reference signals,
when reprogram operation is performed in a first data state in which a first logic value or a second logic value is written in the data storage area,
then if information in the reprogram information storage area is less than a first setting value and the high-speed program mode signal terminal is valid, reprogram information obtained by adding one to the number of reprogram operations is written to the reprogram information storage area, and based on the information indicating the number of reprogram operations stored in the reprogram information storage area, one is selected from the plurality of read reference signals, and with reference to the selected read reference signal, data is written into a second data state different from the first data state, or
then if the information in the reprogram information storage area is not less than the first setting value or the high-speed program mode signal terminal is invalid,
then if the information in the reprogram information storage area is less than a second setting value, reprogram information obtained by adding one to the number of reprogram operations is written to the reprogram information storage area, and based on the information indicating the number of reprogram operations stored in the reprogram information storage area, one is selected from the plurality of read reference signals, and with reference to the selected read reference signal, data is written into the second data state different from the first data state, or
then if the information in the reprogram information storage area is the second setting value, the data storage area and the reprogram information storage area are erased, and based on the information indicating the number of reprogram operations stored in the reprogram information storage area, one is selected from the plurality of read reference signals, and with reference to the selected read reference signal, data is written into the second data state different from the first data state, and
the first and second predetermined values are set in association with the plurality of possible read reference signals, and the first predetermined value is greater than the second predetermined value.

26. The method of claim 24, wherein
the plurality of read reference signals are M different read reference signals, where M is two or more,
the selection of the plurality of read reference signals is selection of a specific one from the M read reference signals,
the data states are M different data states, where M is two or more, and
in the program operation, data is written into one of the M data states.

27. The non-volatile semiconductor memory device of claim 11, wherein the plurality of storage states of each memory cell are a plurality of threshold values.

28. The non-volatile semiconductor memory device of claim 11, wherein the plurality of storage states of each memory cell are a plurality of resistance values.

29. The non-volatile semiconductor memory device of claim 11, wherein the read reference signal indicates a read reference current value.
